(19) United States
(12) Patent Application Publication
(10) Pub. No.: US 2004/0062896 A1
(43) Pub. Date: Apr. 1, 2004

(54) Fractionally-releasable bonding layer for use in photo-sensitive laminate films

(76) Inventors: Terrence F. Picone, Ramsey, NJ (US); Steven C. Schaffer, Danbury, CT (US)

Correspondence Address: Clifford L. Tager, Esq., One Hudson Street, Bethel, CT, 06801, US

(21) Appl. No.: 10/256,154

(22) Filed: Sep. 26, 2002

(51) Int. Cl. B32B 9/00; B32B 3/10; G03F 7/09; G03F 7/40; G03F 7/16; B05D 1/32; B44C 1/22

(52) U.S. Cl. 428/40.1; 428/137; 428/195.1; 430/14; 430/18; 430/260; 430/272.1; 430/271.1; 430/323; 430/324; 427/282; 216/43; 216/47

(57) ABSTRACT

The present invention is directed to a photo-sensitive laminate film for use in making an image mask for etching an image on a substrate. In a first preferred embodiment, the photo-sensitive laminate film comprises a support sheet having a first surface and a second surface, a layer of polymer resin composition having photocrosslinkability, the layer of polymer resin composition having a first surface and a second surface, and a fractionally-releasable bonding layer located between the first surface of the support sheet and the second surface of the layer of polymer resin composition. Upon the creation of an image mask from the layer of polymer resin composition, the image mask is capable of being separated from the first surface of the support sheet such that at least a portion of the bonding layer located between the image mask and the first surface of the support sheet is released from the support sheet with the image mask, and the remaining portion of the bonding layer remains with the support sheet. In use, the image mask, defined by a predetermined pattern, can be operatively attached to a substrate, the support sheet can be removed, and the substrate can be etched (e.g., either by sandblasting or by the application of a chemical etching solution) with an image corresponding inversely to the predetermined pattern of the image mask.

### BACKGROUND OF THE INVENTION

1. Technical Field

The present invention is directed to a fractionally-releasable bonding layer.

More particularly, the present invention is directed to a fractionally-releasable bonding layer for use in photo-sensitive laminate films used to create image masks, and finds particular utility in facilitating the transfer of the image mask to a substrate for applications involving etching a pattern onto the substrate.

As used herein, the term “etching” shall mean the creation of an image or other pattern on a substrate, such as by sandblasting or the application of a chemical etching solution.

The present invention also finds utility in applications where the creation and/or use of an image mask is desired or otherwise applicable, e.g., for circuit board design, glue chipping, and using the image mask as a border in painting or gold leaf applications.

The present invention is also equally suitable in applications where it is desirable to facilitate the transfer of art work or other images onto a substrate.

2. Background Information

Photo-sensitive laminate films for creating image masks are known in the art. For example, U.S. Pat. No. 5,427,890 to Suzuki, et al., assigned to Aicello Chemical Co., Ltd., discloses a photosensitive laminate film having a support sheet, a layer of water-soluble resin composition having photocrosslinkability, and an image mask protection layer therebetween.

In use, a positive image is placed on the surface of the layer of water-soluble resin composition and the laminate film is exposed to actinic radiation, such as a metal halide lamp, for a predetermined time period. The actinic radiation passes through the transparent portions of the image, impinging upon the water-soluble resin composition located below the transparent portions of the image, causing that portion of the water-soluble resin composition to be crosslinked, i.e., cured so as not to be water-soluble.

Thereafter, the positive image is removed, and the laminate film is immersed in and sprayed with water. The water causes the non-crosslinked portions of the water-soluble resin composition to swell as a result of the absorption of water and be dissolved and washed away by the pressure of the spray. The crosslinked resin composition which was not washed away is a negative of the image, and is commonly referred to as an image mask.

At this point, the image mask is still adhered to the support sheet via the image mask protection layer located therebetween. Once the upper surface of the image mask is adhered to a surface of a substrate to be sandblasted, the support sheet is peeled away from the image mask protection layer, leaving the solid layer of the image mask protection layer adhered to the image mask.

It should be noted that the image mask protection layer is located across the entire image mask, including the voids in the image mask which represent the positive image. Sandblasting first removes the image mask protection layer located over the voids before being able to sandblast that portion of the substrate not covered by the image mask adhered thereto.

While the above represents an adequate method for sandblasting, it is often desirable to etch the surface of a substrate with a chemical etching solution. To do so using the above method, the solid layer of the image mask protection layer located over the voids in the image mask must first be removed or dissolved before the chemical etching solution is able to contact that portion of the surface of the substrate not covered by the image mask.

It is typically not practical to cut away the portions of the image mask protection layer which cover the voids, since same is a time-consuming step, and the pattern formed by the crosslinked resin composition would be susceptible to damage.

Using the chemical etching solution to remove the unwanted portions of the image mask protection layer also represents a time-consuming step, as well as an increase in the amount of chemical etching solution required for the job.

### SUMMARY OF THE INVENTION

The present invention is directed to a photo-sensitive laminate film for use in making an image mask for etching an image on a substrate.

In a first preferred embodiment of the present invention, the photo-sensitive laminate film comprises a support sheet having a first surface and a second surface, a layer of polymer resin composition having photocrosslinkability, the layer of polymer resin composition having a first surface and a second surface, and a fractionally-releasable bonding layer located between the first surface of the support sheet and the second surface of the layer of polymer resin composition.

Upon the creation of the image mask from the layer of polymer resin composition, the image mask having at least one portion of crosslinked polymer resin composition and at least one portion devoid of any crosslinked polymer resin composition, the support sheet is capable of being separated from the image mask such that substantially all of the bonding layer which is not located between the image mask and the first surface of the support sheet remains with the support sheet.

In use, the image mask, defined by a predetermined pattern, can be operatively attached to a substrate, the support sheet can be removed, and the substrate can be etched (e.g., either by sandblasting or by the application of a chemical etching solution) with an image corresponding inversely to the predetermined pattern of the image mask.

The support sheet is preferably either a siliconized polyester film or a non-siliconized polyester film. Optionally, the support sheet can be either substantially opaque or comprise an actinic radiation blocker to reduce the effects of accidental actinic radiation exposure of the polymer resin composition through the support sheet.

The fractionally-releasable bonding layer is preferably formed by combining a bonding agent and a carrier agent to form a bonding layer solution, applying the bonding layer solution to the first surface of the support sheet, and allowing the bonding layer solution to evaporate, thereby resulting in the formation of the fractionally-releasable bonding layer on the first surface of a support sheet.

The bonding agent preferably comprises a member selected from the group consisting of ethylcellulose, polyvinyl acetate, cellulose acetate, cellulose nitrate, polyvinyl acetate chemically reacted with pyrrolidone copolymer, polyvinyl pyrrolidone and polyvinyl alcohol.

The carrier agent preferably comprises a member selected from the group consisting of an aromatic hydrocarbon, a hydro-aromatic hydrocarbon, a naval store, a chlorinated aliphatic hydrocarbon, a chlorinated aromatic hydrocarbon, a monohydric cyclic alcohol, an ether alcohol, an ether and an acetate.

Optionally, an actinic radiation blocker, an antioxidant and/or a plasticizer can be combined with the bonding layer solution prior to applying the bonding layer solution to the first surface of the support sheet.

The bonding layer solution can be applied to the support sheet either via a spray process or a coating process.

Where the bonding agent comprises ethylcellulose, the carrier agent comprises toluene and a viscosity reducer, and the bonding layer solution is applied to the first surface of a support sheet via a spray process, the amount of the bonding agent is preferably between about 2% and about 17% of the carrier agent by weight, and the ratio of toluene to the viscosity reducer is preferably between about 60:40 to about 100:0 of the carrier agent by weight.

Where the bonding agent comprises ethylcellulose, the carrier agent comprises toluene and a viscosity reducer, and the bonding layer solution is applied to the first surface of a support sheet via a coating process, the amount of the bonding agent is preferably between about 0.5% and about 2% of the carrier agent by weight, and the ratio of toluene to the viscosity reducer is preferably between about 87:13 to about 100:0 of the carrier agent by weight.

Where the bonding agent comprises polyvinyl acetate, the carrier agent comprises toluene and a viscosity reducer, and the bonding layer solution is applied to the first surface of a support sheet via a spray process, the amount of the bonding agent is preferably between about 5% and about 18% of the carrier agent by weight, and the ratio of toluene to the viscosity reducer is preferably between about 70:30 to about 99:1 of the carrier agent by weight.

Where the bonding agent comprises polyvinyl acetate, the carrier agent comprises toluene and a viscosity reducer, and the bonding layer solution is applied to the first surface of a support sheet via a coating process, the amount of the bonding agent is preferably between about 2% and about 7% of the carrier agent by weight, and the ratio of toluene to the viscosity reducer is preferably between about 70:30 to about 99:1 of the carrier agent by weight.

In the preferred embodiment, the viscosity reducer comprises ethyl alcohol.

The photo-sensitive laminate film optionally further comprises a protective layer removably-attached to the first surface of the layer of polymer resin composition, the protective layer being removable therefrom prior to the creation of the image mask.

The protective layer is preferably either substantially opaque or comprises an actinic radiation blocker to reduce the effects of accidental actinic radiation exposure of the polymer resin composition through the protective layer.

Since both the support sheet and the protective layer are removable (the protective layer before the creation of the image mask; the support sheet after the creation of the image mask), the protective layer is preferably distinguishable from the support sheet to clarify that it is the protective layer and not the support sheet which is removable prior to the creation of the image mask.

In a second preferred embodiment of the present invention, the photo-sensitive laminate film for use in making an image mask for etching an image on a substrate comprises a layer of polymer resin composition having photocrosslinkability, the layer of polymer resin composition having a first surface and a second surface, a support sheet having a first surface operatively attached to the second surface of the layer of polymer resin composition and a second surface, a layer of adhesive operatively affixed to the second surface of the support sheet, and an adhesive protection layer removably adhered to the layer of adhesive.

Upon the creation of an image mask from the layer of polymer resin composition, the image mask is capable of being operatively attached to the substrate by removing the adhesive protection layer and applying the layer of adhesive located on the second surface of the support sheet to the substrate. Thereafter, the substrate is capable of being etched via sandblasting through the support sheet to create an image corresponding inversely to the image mask.

In a third preferred embodiment of the present invention, the photo-sensitive laminate film comprises a layer of polymer resin composition having photocrosslinkability, the layer of polymer resin composition having a first surface and a second surface, and a support sheet having a first surface operatively attached to the second surface of the layer of polymer resin composition.

Upon the creation of an image mask from the layer of polymer resin composition, the support sheet is capable of being attached to the substrate by applying a layer of adhesive between a second surface of the support sheet and the substrate. Thereafter, the substrate is capable of being etched via sandblasting through the support sheet to create an image corresponding inversely to the image mask.

In both the second and third preferred embodiments, the support sheet is preferably a non-siliconized polyester film, and optionally is either opaque or comprises an actinic radiation blocker to reduce the effects of accidental actinic radiation exposure of the polymer resin composition through the support sheet.

The photo-sensitive laminate film optionally further comprises a protective layer removably-attached to the first surface of the layer of polymer resin composition, the protective layer being removable therefrom prior to the creation of the image mask.

The protective layer is preferably either opaque or comprises an actinic radiation blocker to reduce the effects of accidental actinic radiation exposure of the polymer resin composition through the protective layer.

Since both the support sheet and the protective layer are removably (the protective layer before the creation of the image mask; the support sheet after the creation of the image mask), the protective layer is preferably distinguishable from the support sheet to clarify that it is the protective layer and not the support sheet which is removable prior to the creation of the image mask.

In a fourth preferred embodiment of the present invention, the photo-sensitive laminate film comprises a support sheet having a first surface and a second surface, and a fractionally-releasable bonding layer having a first surface and a second surface, the first surface of the bonding layer located on the second surface of the support sheet.

In use, an image is capable of being applied to at least a portion of the second surface of the bonding layer, and the support sheet is capable of being separated from the image.

An image is preferably applied to the second surface of the bonding layer by placing a stencil having a first surface and a second surface in juxtaposition with the fractionally-releasable bonding layer such that the second layer of the stencil is in juxtaposition with the fractionally-releasable bonding layer. The stencil preferably has at least a first predetermined portion which allows fluid flow therethrough and at least a second predetermined portion which does not allow fluid flow therethrough.

A fluid is then preferably applied on the first surface of the stencil such that at least a portion of the fluid which is applied over the first predetermined portion of the stencil passes therethrough to be deposited onto the fractionally-releasable bonding layer as the image. Thereafter, the stencil is preferably removed therefrom.

In applications where the stencil is used to create an image to be applied to a substrate for etching, the fluid is preferably a rubberized ink. The image can then be operatively attached to a substrate, and the support sheet can be removed therefrom, thereby separating the image from the support sheet.

In applications where the stencil is used to create an image to be applied to the surface of a substrate as artwork or other ornamental feature or design, the fluid preferably comprises a colored medium, such as paint.

In such applications, a plurality of stencils, each having its own pattern, can be used with a plurality of different paints. The resulting artwork image can be operatively attached to a substrate, and the support sheet can be removed therefrom, thereby separating the artwork image from the support sheet.

### BRIEF DESCRIPTION OF THE DRAWINGS

FIG. 1 illustrates a cut-away side view of a first preferred embodiment of the photo-sensitive laminate film of the present invention.

FIG. 2 depicts a cut-away side view of the photo-sensitive laminate film shown in FIG. 1 with a developed image mask.

FIG. 3 shows a cut-away top view of the image mask of FIG. 2 adhered to a surface of a substrate to be etched.

FIG. 4 sets forth an embodiment for a preferred curtain coating process.

FIG. 5 illustrates a cut-away side view of another preferred embodiment of the photo-sensitive laminate film of the present invention.

FIG. 6 shows a cut-away side view of an additional preferred embodiment of the photo-sensitive laminate film of the present invention.

FIG. 7 depicts a cut-away side view of another preferred embodiment of the photo-sensitive laminate film of the present invention.

FIG. 8 shows a cut-away side view of a further preferred embodiment of the photo-sensitive laminate film of the present invention.

FIG. 9 illustrates a cut-away side view of the embodiment of FIG. 8 with an image thereon.

### DESCRIPTION OF THE PREFERRED EMBODIMENT(S)

The present invention is directed to a fractionally-releasable bonding layer.

More particularly, the present invention is directed to a fractionally-releasable bonding layer for use in photo-sensitive laminate films used to create image masks, and finds particular utility in facilitating the transfer of the image mask to a substrate for applications involving etching a pattern onto the substrate.

As used herein, the term “etching” shall mean the creation of an image or other pattern on a substrate, such as by sandblasting or the application of a chemical etching solution.

The present invention also finds utility in applications where the creation and/or use of an image mask is desired or otherwise applicable, e.g., for circuit board design, glue chipping, and using the image mask as a border in painting or gold leaf applications.

The present invention is also equally suitable in applications where it is desirable to facilitate the transfer of art work or other images onto a substrate.

While the present invention is described hereinbelow with reference to these particular applications, it is to be understood that the present invention is not so limited.

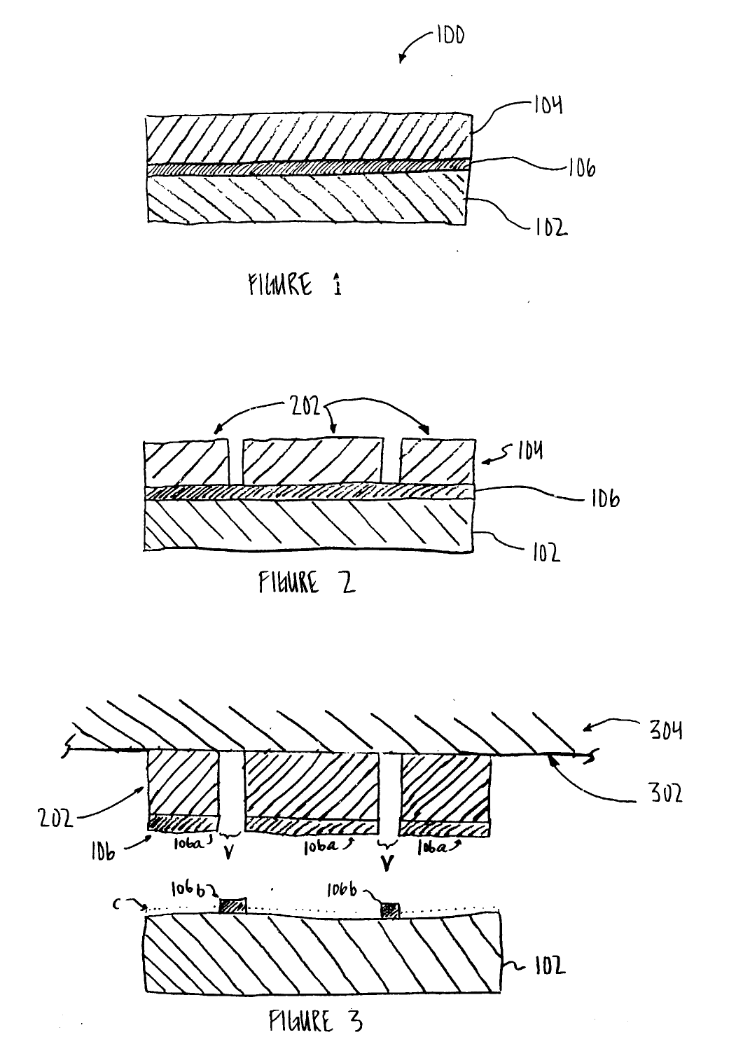

Turning now to FIG. 1, a cut-away side view of a first preferred embodiment of the photo-sensitive laminate film of the present invention is illustrated.

Photo-sensitive laminate film 100 preferably comprises support sheet 102, layer of polymer resin composition having photocrosslinkability 104, and fractionally-releasable bonding layer 106 located therebetween.

Support sheet 102 is preferably a polyester film. Alternatively, support sheet 102 can be any other flexible material able to support both fractionally-releasable bonding layer 106 and layer of polymer resin composition having photocrosslinkability 104, e.g., a film comprising polyethylene, polyethylene terephthalate, polypropylene, polyvinyl acetate, polyvinyl butanol, polyvinyl chloride, polycarbonate, ethylcellulose, cellulose acetate, cellulose nitrate, cellophane, paper, cloth, nylon, aluminum foil or tin. Other materials will be apparent to one skilled in the art having knowledge of the present specification.

In the preferred embodiment, support sheet 102 has a thickness between about 1 mil and about 25 mils, more preferably between about 2 mils and about 10 mils, and most preferably between about 3 mils and about 4 mils. Other thicknesses, dependent upon the specific application, will be apparent to one skilled in the art having knowledge of the present specification.

The surface of support sheet 102 onto which fractionally-releasable bonding layer 106 is located is optionally coated, treated or otherwise impregnated with silicone, as known in the art.

Alternatively, the surface of support sheet 102 can be coated, treated or otherwise impregnated with silicone having a secondary component to control the release properties thereof, such as tin.

In lieu of silicone, the surface of support sheet 102 can be treated with a non-silicone release system, as will be apparent to one skilled in the art having knowledge of the present specification.

A preferred support sheet which has not been coated, treated or otherwise impregnated with silicone is Polyester 770, a non-coronaized polyester film having an anti-static coating manufactured by and available from DuPont Corporation, of Wilmington, Del.

A preferred support sheet which has been coated with silicone is a siliconized polyester film such as T-30 to T-100, more preferably T-90, each manufactured by and available from CPFilms, Inc., of Martinsville, Va.

Layer 104 is preferably a polymer resin composition having photocrosslinkability.

Both water-soluble and water-insoluble polymer resin compositions having photocrosslinkability are known in the art. Examples of water-soluble polymer resin compositions include those compositions described in the following U.S. Pat. No. 6,235,449 to Souders, et al.; U.S. Pat. Nos. 6,037,106 and 5,989,689, both to Komatsu; U.S. Pat. Nos. 5,629,132, 5,518,857 and 5,427,890, all to Suzuki, et al.; U.S. Pat. Nos. 5,445,916, 5,358,999 and 5,326,669, all to Curtis; U.S. Pat. No. 5,415,971 to Couture, et al.; U.S. Pat. No. 4,764,449 to Vanlseghem; U.S. Pat. Nos. 4,587,186 and 4,456,680, both to Nakamura, et al.; and U.S. Pat. No. 4,544,619 to Christensen, et al. Examples of water-insoluble polymer resin compositions include those compositions described in Japanese Patent Unexamined publications Kokai Sho 55-96270 and Kokai Sho 60-104939. The above references are incorporated herein by reference.

As appreciated by those skilled in the art, polymer resin compositions comprise a photocrosslinking agent which, when exposed to actinic radiation, causes the exposed portions thereof to crosslink, or bond together, effectively curing those portions exposed to the actinic radiation.

In the preferred embodiment, polymer resin composition 104 is water-soluble, such as QTX or QTP, both manufactured by and available from Ulano Corporation of Brooklyn, New York.

As used herein, the term “actinic radiation” is defined as that range of wavelengths which causes the exposed portions of the polymer resin composition to crosslink. As understood by those skilled in the art, different polymer resin compositions are designed to be sensitive to and become crosslinked at different wavelengths. The preferred polymer resin composition, QTX or QTP, is sensitive to wavelengths from about 340 nanometers (nm) to about 400 nm, centering at about 365 nm.

In the preferred embodiment, polymer resin composition 104 has a thickness between about 1 mil and about 30 mils, more preferably between about 2 mils and about 10 mils, and most preferably between about 3 mils and about 5 mils. Other thicknesses, dependent upon the specific application, will be apparent to one skilled in the art having knowledge of the present specification.

Fractionally-releasable bonding layer 106 is preferably located between support sheet 102 and polymer resin composition 104 to both bond the polymer resin composition to the support sheet, as well as to allow an image mask created from the layer of polymer resin composition to be removable from the support sheet.

An image mask is typically created from a layer of water-soluble polymer resin composition by placing a positive image face-down on the surface of polymer resin composition 104. The positive image comprises both opaque (i.e., actinic radiation blocking) areas, representing that portion of the positive image which a user desires to have etched onto the surface of a substrate, either by sandblasting or the application of a chemical etching solution, and transparent (i.e., non-actinic radiation blocking) areas, representing that portion of the positive image which are not to be etched onto the substrate's surface.

After placing the positive image face-down (i.e., opaque-image side down) on the layer of polymer resin composition 104, the positive image and underlying laminate film are exposed to actinic radiation, such as direct sunlight, a metal halide lamp or a BL black light bulb, for a predetermined time period. Other sources of actinic radiation will be apparent to one skilled in the art having knowledge of the present specification.

The actinic radiation passes through the transparent portions of the positive image, impinging upon the polymer resin composition located directly below the transparent portions of the positive image, causing that portion of the polymer resin composition to be crosslinked, i.e., cured so as not to be water-soluble.

As the actinic radiation does not pass through the opaque portions of the positive image, the areas under the opaque portions are not crosslinked and thus remain water soluble.

The positive image is then removed, and the laminate film is washed with water, for example, using a pressurized water spray from a faucet or garden hose. The non-crosslinked portions of the water-soluble resin composition begin dissolving on contact with the water, and are preferably completely washed away by the pressure of the spray.

An image mask created from a layer of water-insoluble polymer resin composition would follow the above typical methodology, except that, where the polymer resin composition is water-insoluble, the non-crosslinked portions would remain water-insoluble after exposure to actinic radiation and would be washed away via contact with an applicable solvent solution.

With reference to FIG. 2, the crosslinked resin composition which remains adhered to support sheet 102 after the non-crosslinked portions of the polymer resin composition have been washed away is a negative of the positive image, and is commonly referred to as an image mask, shown as reference 202.

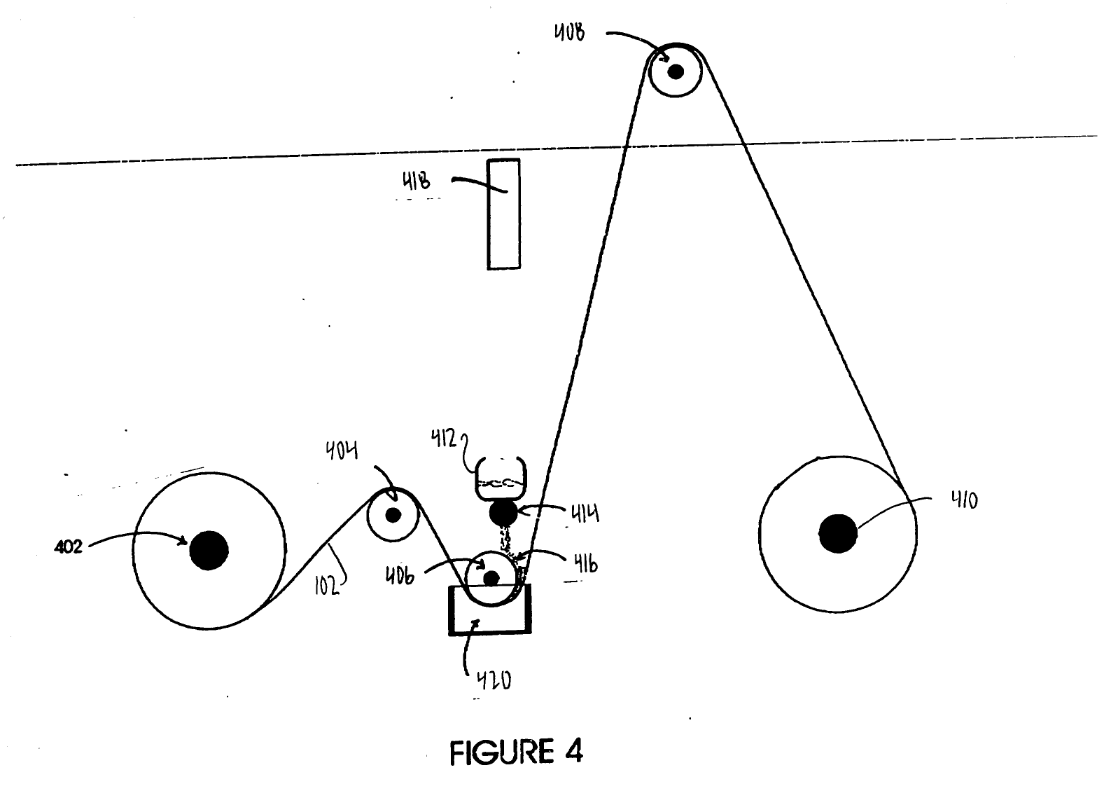

In use, and with reference to FIG. 3, the top surface of image mask 202 (i.e., that surface not attached to support sheet 102) is operatively attached to surface 302 of substrate 304 to be etched and support sheet 102 is separated therefrom.

Preferably, bonding layer 106 is fractionally-releasable, thereby allowing image mask 202 to be separated from support sheet 102 such that at least a portion of the bonding layer which is located between the image mask and the support sheet, i.e., 106a, is released from the support sheet with the image mask, and the remaining portions of the bonding layer, i.e., 106b, remain with the support sheet.

A portion of bonding layer 106 located between the image mask and the support sheet may not fully transfer with the image mask upon removal of support sheet 102, as indicated by reference 106c, which is acceptable.

However, it should be noted that, in the preferred embodiment, substantially little, if any, of the bonding layer which is in juxtaposition with void areas V of the image mask (i.e., 106b) transfer with the image mask. Rather, substantially all such portions remain with the support sheet.

Thus, unlike the prior art, such as U.S. Pat. No. 5,427,890 to Suzuki, et al., assigned to Aicello Chemical Co., Ltd. (discussed above), the bonding layer of the present invention is not covering or otherwise blocking the void areas V of the image mask after the image mask has been separated from the support sheet, in contrast to the solid film image mask protection layer of Suzuki, et al. Thus, the portion of surface 302 of substrate 304 which is exposed by void areas V is directly accessible for etching, either by sandblasting or by application of a chemical etching solution.

Accordingly, the problems inherent with the prior art (i.e., where a solid film image mask protection layer is located across the entire image mask, including the void areas in the image mask which represent the positive image) are avoided by the present invention. Thus, for example, the prior art step of first removing portions of the solid film image mask protection layer to access the void areas in the image mask is eliminated.

During the etching process, image mask 202 protects that portion of the substrate to which the image mask is adhered. Thus, only the exposed surfaces of the substrate, i.e., those portions which do not have the image mask adhered thereto, are affected by the sandblasting or chemical etching solution.

Where the resulting image mask will be used in sandblasting applications, a plasticizer is preferably added to the polymer resin composition to enhance its elasticity. In this way, the image mask created therefrom is better able to withstanding the repeated abrasive impacts received during the sandblasting process.

The plasticizer is preferably compatible with the bonding agent (described in detail below) of bonding layer 106. In the preferred embodiment, the plasticizer is BENZOFLEX 50, manufactured by and available from Velsicol Chemical Corporation, of Rosemont, Illinois. The use of other plasticizers, either in addition to in lieu of BENZOFLEX 50, will be apparent to one skilled in the art having knowledge of the present specification.

In the preferred embodiment, the amount of plasticer added to the polymer resin composition has a range from about 0.5% to about 5% of the polymer resin composition by weight, and more preferably about 1% by weight. Variations in the amount of plasticizer added to the polymer resin composition will be dependent upon the specific application.

For example, in applications where the substrate will be sandblasted for an extended period of time, either because the substrate is relatively adamantine or in order to impart a relatively deeply-etched pattern, it may be desirable to use a higher percentage of plasticizer. Alternatively, the thickness of the polymer resin composition layer may be increased to withstand prolonged sandblasting.

In the preferred embodiment, fractionally-releasable bonding layer 106 is located between the layer of polymer resin composition 104 and support sheet 102 for several reasons.

Specifically, the fractionally-releasable bonding layer allows the polymer resin composition to bond to both a siliconized as well as a non-siliconized polyester support sheet, while also allowing the image mask created from the polymer resin composition to separate from the support sheet without any distortion to or the loss of any fine details in the image mask.

As will be appreciated by those skilled in the art, a water-soluble polymer resin composition is capable of adhering directed to a non-siliconized support sheet of polyester film. However, the degree of adhesion therebetween is relatively high.

On a microscopic level, the surface of a typical non-siliconized polyester film is not smooth, but rather is uneven and contains multiple micro-pits and depressions.

The polymer resin composition, which is typically applied in liquid form to the support sheet and then generally exposed to heat to facilitate the drying process, adheres to the depressions in the surface of the polyester film, resulting in the relatively high degree of adhesion therebetween.

While such adhesion may be suitable for some applications, it is not suitable for applications in which the resulting image mask will contain relatively fine details, since such fine details may remain, either in whole or in part, with the support sheet and not transfer to the substrate to be etched when the support sheet is removed from the image mask.

Thus, in use, any relatively fine details contained in the image mask which are not fully released from the support sheet and transferred to the substrate will cause an inaccurate and/or distorted image to be etched onto the substrate.

On the other hand, a water-soluble polymer resin composition is not capable of adhering directed to a siliconized polyester support sheet. Rather, testing has shown that such water-based polymer resin compositions are generally repelled by the siliconized surface of the polyester film.

To overcome the above problems, fractionally-releasable bonding layer 106 is preferably located between support sheet 102 and polymer resin composition 104. Fractionally-releasable bonding layer 106 allows the polymer resin composition to bond to both siliconized as well as non-siliconized support sheets, while allowing the image mask created from the polymer resin composition to separate from the support sheet and transfer to a substrate without loss of or damage to any fine details contained in the image mask.

In the preferred embodiment, fractionally-releasable bonding layer 106 is applied to support sheet 102 as a bonding layer solution comprising a bonding agent and a carrier agent.

Once the bonding agent is mixed with the carrier agent, the resulting bonding layer solution can be applied to the surface of the support sheet by any conventional method, including but not limited to spraying, rolling, gravure coating, curtain coating, knife coating, air coating, dipping, printing, and the like. Other methods of applying the bonding layer solution to the support sheet will be apparent to one skilled in the art having knowledge of the present specification.

The bonding agent can be water soluble or water insoluble.

Examples of water soluble bonding agents include polyvinyl pyrrolidone and polyvinyl alcohol. Examples of water insoluble bonding agents include ethylcellulose, polyvinyl acetate, cellulose acetate, cellulose nitrate (also known as nitrocellulose), and polyvinyl acetate chemically reacted with pyrrolidone copolymer.

Where the specific application will produce an image mask having a relatively high degree of detail, the bonding agent is preferably water insoluble when the polymer resin composition is water-soluble, and visa versa. In this way, for example, the process of removing the non-crosslinked portions of a water-soluble polymer resin composition by exposure to water will not also interfere with and/or remove the portions of the bonding layer underlying the resulting image mask, since the removal thereof may also cause the premature removal of any portion of the image mask from the support sheet.

In the preferred embodiment, the bonding agent comprises a water-insoluble compound such as ethylcellulose, polyvinyl acetate or cellulose acetate. A preferred ethylcellulose is ETHOCELL STD-10, manufactured by and available from The Dow Chemical Company, or AQUALON Ethylcellulose, N-Type, manufactured by and available from Hercules Incorporated, of Wilmington, Del.

In applications in which the bonding agent is ethylcellulose and the bonding layer solution is sprayed onto the surface of the support sheet, it has been found that the amount of ethylcellulose preferably comprises from about 2% to about 17% of the carrier agent by weight, more preferably from about 4% to about 12% of the carrier agent by weight, and most preferably from about 7% to about 9% of the carrier agent by weight. For example, where the total weight of the carrier agent is 1000 grams, the amount of ethylcellulose is preferably from about 20 to about 170 grams, more preferably from about 40 to about 120 grams, and most preferably from about 70 to about 90 grams. Other ratios will be apparent to one skilled in the art having knowledge of the present specification.

In applications in which the bonding agent is ethylcellulose and the bonding layer solution is applied onto the surface of the support sheet via a curtain coating method, it has been found that the amount of ethylcellulose preferably comprises from about 0.5% to about 2% of the carrier agent by weight, more preferably from about 0.7% to about 1.5% of the carrier agent by weight, and most preferably from about 0.7% to about 0.9% of the carrier agent by weight. For example, where the total weight of the carrier agent is 1000 grams, the amount of ethylcellulose is preferably from about 5 to about 20 grams, more preferably from about 7 to about 15 grams, and most preferably from about 7 to about 9 grams. Other ratios will be apparent to one skilled in the art having knowledge of the present specification.

In applications in which the bonding agent is polyvinyl acetate and the bonding layer solution is sprayed onto the surface of the support sheet, it has been found that the amount of polyvinyl acetate preferably comprises from about 5% to about 18% of the carrier agent by weight, more preferably from about 7% to about 14% of the carrier agent by weight, and most preferably from about 8% to about 10% of the carrier agent by weight. For example, where the total weight of the carrier agent is 1000 grams, the amount of polyvinyl acetate is preferably from about 50 to about 180 grams, more preferably from about 70 to about 140 grams, and most preferably from about 80 to about 100 grams. Other ratios will be apparent to one skilled in the art having knowledge of the present specification.

In applications in which the bonding agent is polyvinyl acetate and the bonding layer solution is applied onto the surface of the support sheet via a curtain coating method, it has been found that the amount of polyvinyl acetate preferably comprises from about 2% to about 7% of the carrier agent by weight, more preferably from about 2% to about about 6% of the carrier agent by weight, and most preferably from about 3% to about 4% of the carrier agent by weight. For example, where the total weight of the carrier agent is 1000 grams, the amount of polyvinyl acetate is preferably from about 20 to about 70 grams, more preferably from about 20 to about 60 grams, and most preferably from about 30 to about 40 grams. Other ratios will be apparent to one skilled in the art having knowledge of the present specification.

The preferred bonding agents identified above are typically available as a solid, preferably in powder form. In order for the bonding agent to be applied to support sheet 102, the bonding agent is preferably dissolved in a liquid, i.e., the carrier agent.

The carrier agent can be any solution which will dissolve the bonding agent therein. Examples of carrier agents which can dissolve the preferred bonding agents include: an aromatic hydrocarbon such as toluene, xylene, ethyl benzene or isopropyl benzene; a hydro-aromatic hydrocarbon such as cyclohexene; a naval store such as dipentene; a chlorinated aliphatic hydrocarbon such as chloroform, carbon tetrachloride, ethylene dichloride, trichloroethylene, propylene dichloride, trichloroethane, perchloroethylene, tetrachloroethane or methylene chloride; a chlorinated aromatic hydrocarbon such as monochlorobenzene, o-dichlorobenzene or trichlorobenzene; a monohydric cyclic alcohol such as furfuryl alcohol, methyl cyclohexanol, tetrahydro-furfuryl alcohol, benzyl alcohol, phenyl ethyl alcohol or pine oil; an ether alcohol such as glycol ether; an ether such as dioxane or morpholine; an acetate such as methyl acetate (99%), ethyl acetate (85-88%), or isopropyl acetate; or an ether such as mesityl oxide, diacetone alcohol, cyclohexanone, methyl cyclohexanone or acetophenone. See, e.g., ETHOCEL Polymers for General Applications product booklet, form number 192-00818-398GW, published by The Dow Chemical Company (March 1998), and Aqualon® Ethylcellulose (EC) Physical and Chemical Properties product booklet, literature number 250-42A 1-00 1M, published by Hercules Incorporated (1996), both of which are incorporated herein by reference.

In the preferred embodiment, the carrier agent comprises toluene.

While toluene has been tested to satisfactorily dissolve ethylcellulose and polyvinyl acetate in the above preferred concentrations, the resulting bonding layer solution is relatively viscous.

Accordingly, it has been found that the carrier agent preferably further comprises a viscosity reducer to facilitate the application of the bonding layer solution onto the support sheet. In the preferred embodiment, the viscosity reducer comprises ethyl alcohol. Other viscosity-reducing agents will be apparent to one skilled in the art having knowledge of the present specification.

In applications in which the bonding layer solution is sprayed onto the surface of the support sheet, the addition of ethyl alcohol reduces the viscosity of the bonding layer solution, thereby facilitating the spray process, since the bonding layer solution is relatively thinner and thus easier to spray.

The addition of ethyl alcohol has the further effect of retarding the rate of evaporation of the carrier agent, since the ethyl alcohol raises the evaporation point of the carrier agent. This effect is beneficial to the spraying process, since it allows the bonding layer solution sufficient time to travel from the spray gun to the surface of the support sheet, and for the bonding agent located therein to adhere to the surface of the support sheet prior to evaporation of the carrier agent. Otherwise, the carrier agent may substantially evaporate during transit of the bonding layer solution through the ambient air, resulting in insufficient adhesion of the bonding agent to the surface of the support sheet.

By raising the evaporation point of the carrier agent, the bonding layer solution becomes less sensitive to the temperature of the ambient air during the spray process, thereby allowing the spray process to occur in a greater range of ambient temperatures.

In applications in which the bonding layer solution is applied to the surface of the support sheet via a curtain coating method, it has been found that reducing the viscosity of the bonding layer solution by the addition of ethyl alcohol facilitates the deposit of a thin-film of bonding layer solution onto the surface of the support sheet. Specifically, ethyl alcohol decreases the surface tension of the bonding layer solution, thereby promoting the flow and lateral dispersion of the bonding layer solution.

In applications in which the bonding agent is ethylcellulose and the bonding layer solution is sprayed onto the surface of the support sheet, it has been found that the carrier agent preferably comprises toluene from about 60% to about 100% of the carrier agent by weight, more preferably from about 70% to about 95% of the carrier agent by weight, and most preferably from about 86% to about 94% of the carrier agent by weight; the remainder thereof being ethyl alcohol, if applicable. Other percentages will be apparent to one skilled in the art having knowledge of the present specification.

In applications in which the bonding agent is ethylcellulose and the bonding layer solution is applied onto the surface of the support sheet via a curtain coating method, it has been found that the carrier agent preferably comprises toluene from about 87% to about 100% of the carrier agent by weight, more preferably from about 90% to about 97% of the carrier agent by weight, and most preferably from about 92% to about 95% of the carrier agent by weight; the remainder thereof being ethyl alcohol, if applicable. Other percentages will be apparent to one skilled in the art having knowledge of the present specification.

In applications in which the bonding agent is polyvinyl acetate and the bonding layer solution is sprayed onto the surface of the support sheet, it has been found that the carrier agent preferably comprises toluene from about 70% to about 100% of the carrier agent by weight, more preferably from about 83% to about 95% of the carrier agent by weight, and most preferably from about 86% to about 94% of the carrier agent by weight; the remainder thereof being ethyl alcohol, if applicable. Other percentages will be apparent to one skilled in the art having knowledge of the present specification.

In applications in which the bonding agent is polyvinyl acetate and the bonding layer solution is applied onto the surface of the support sheet via a curtain coating method, it has been found that the carrier agent preferably comprises toluene from about 70% to about 100% of the carrier agent by weight, more preferably from about 90% to about 97% of the carrier agent by weight, and most preferably from about 92% to about 95% of the carrier agent by weight; the remainder thereof being ethyl alcohol, if applicable. Other percentages will be apparent to one skilled in the art having knowledge of the present specification.

It has been found that the upper limit on the amount of ethyl alcohol preferably added to the carrier agent is dependent on the percentage of bonding agent in the bonding layer solution. Specifically, if too much ethyl alcohol is present in the bonding layer solution for a given amount of ethylcellulose, the bonding layer solution turns cloudy, indicating an incomplete dissolving of the ethylcellulose crystals, and the resulting bonding layer from the application thereof is a fine, powdery layer which is not operatively adhered to the surface of the support sheet, and therefore is not satisfactory.

It is believed that the addition of excessive ethyl alcohol interferes with the formation of long-chain molecules formed by the ethylcellulose as it is dissolved in the carrier agent, thereby adversely affecting the characteristics of the resulting bonding layer.

Similarly, if too much ethyl alcohol is present in the bonding layer solution for a given amount of polyvinyl acetate, the resulting bonding layer is slightly crystalline and granular in structure, is not operatively adhered to the surface of the support sheet, and therefore is not satisfactory.

As discussed above, the bonding layer solution can be applied to the surface of the support sheet by any conventional method. In the preferred embodiment, the bonding layer solution is applied via a spray method or a curtain coating method.

A preferred spray method comprises spraying the bonding layer solution onto the support sheet in a discontinuous pattern, such as a periodically and/or randomly interrupted, micro-dot pattern wherein the micro-dots are located in very close proximity to each other, some of which overlap each other, some of which do not.

In the preferred spray method, the bonding layer solution is sprayed onto the support sheet using a pressurized spray gun having a nozzle which preferably emits a fan-shaped spray pattern. The nozzle is preferably located about 12-14 inches away from the surface of the support sheet, and the bonding layer solution is sprayed onto the surface of the support sheet using a 50% overlapping spray technique, preferably achieving at least 90% coverage.

This spray method preferably produces the preferred dense random micro-dot pattern on the support sheet such that the micro-dots are located in very close proximity to each other, some of which overlap each other, some of which do not.

Warm air is then preferably passed over the support sheet for about 3 minutes to speed the evaporation of the bonding layer solution.

Since the resulting randomized micro-dot pattern is highly fractured and discontinuous, the resulting bonding layer is fractionally-releasable, as discussed above with reference to FIG. 3.

The diameter of the individual micro-dots in the resulting bonding layer (i.e., the layer of micro-dots remaining after the bonding layer solution has fully evaporated) and the thickness of the resulting bonding layer are dependent upon the amount of bonding agent contained in the bonding layer solution, as well as the composition of the carrier agent in the bonding layer solution.

Specifically, the diameter of the individual micro-dots and the thickness of the resulting bonding layer are directly proportional to the amount of bonding agent in the bonding layer solution, and are indirectly proportional to the amount of ethyl alcohol contained in the bonding layer solution.

As the concentration of bonding agent such as ethylcellulose increases, and assuming a homogeneous bonding layer solution which is sprayed as above onto a support sheet, the spray gun will deposit increasingly larger diameter micro-dots in an increasingly thicker layer onto the support sheet, since the bonding layer solution will contain an increasingly greater amount of bonding agent capable of being sprayed.

Additionally, as the concentration of ethyl alcohol in the bonding layer solution increases, the viscosity of the bonding layer solution decreases, as discussed above. The viscosity affects the relative size of the individual micro-dots, the thickness of the resulting bonding layer, as well as the density of the individual micro-dots contained in the resulting bonding layer.

Specifically, as the viscosity of the bonding layer solution decreases, the atomization characteristics of the bonding layer solution being sprayed increases, resulting in smaller particles being sprayed onto the support sheet, thus decreasing the diameter of the individual micro-dots and the thickness of the resulting bonding layer. Increased atomization of the bonding layer solution being sprayed also results in a closer-packed micro-dot pattern.

As discussed above, as the concentration of ethyl alcohol in the bonding layer solution increases, the time required for evaporation of the bonding layer solution increases.

As the relative viscosity of the bonding layer solution decreases (i.e., as the amount of ethyl alcohol increases), an overspray of bonding layer solution increases the chances that the relatively closer-packed micro-dots which form a relatively thinner layer will merge with each other to form a thin-film layer.

For relatively low concentrations of bonding agent (given a constant amount of ethyl alcohol), such micro-dot merger will not adversely affect the fractionability of the resulting bonding layer, since the thin film will be relatively fragile and thus fractionable, as desired.

For relatively high concentrations of bonding agent (given a constant amount of ethyl alcohol), such micro-dot merger may adversely affect the fractionability of the resulting bonding layer, since the thicker the resulting bonding layer film, the less fragile and thus fractionable, it will be.

The diameter of the individual micro-dots in the resulting bonding layer, is preferably from about 0.01 mils to about 5 mils, more preferably from about 0.4 mils to about 0.9 mils, and most preferably from about 0.5 mils to about 0.7 mils. It should be understood that the diameter of the micro-dots can vary based on the relative spacing of the micro-dots in relation to each other. Specifically, where the micro-dots are very closely packed, the diameter of the micro-dots can be smaller, since same creates a suitably fractionable and thus fractionally-releasable layer.

The thickness of the resulting bonding layer is preferably from about 0.004 mils to about 0.5 mils, more preferably from about 0.02 mils to about 0.25 mils, and most preferably from about 0.1 mils to about 0.2 mils.

However, it is to be understood that both the diameter and thickness of micro-dots produced by a spray method will vary considerably, since variations thereof will occur based on the viscosity of the bonding layer solution, the concentration of bonding agent therein, the variations of the air pressure within the dispersion pattern created by the spray gun nozzle, each as discussed above, as well as the ambient conditions such as temperature, humidity and pressure, since ambient conditions will also affect the drying time of the bonding layer solution.

As an alternative to the above spray method which produces discrete micro-dots, where the amount of bonding agent in the bonding layer solution is relatively low, e.g., for ethylcellulose, from about 2% to about 4% of the carrier agent by weight, and for polyvinyl acetate, from about 5% to about 7% of the carrier agent by weight, the spray method can comprise spraying the bonding layer solution onto the support sheet in a continuous, overlapping pattern, preferably depositing a thin-film, substantially uninterrupted, layer of bonding layer solution. After evaporation of the bonding layer solution, the resulting bonding layer is a relatively fragile, thin-film preferably from about 0.1 mils to about 0.5 mils thick, more preferably from about 0.1 mils to about 0.4 mils, and most preferably from about 0.2 mils to about 0.3 mils.

Since the thin-film layer is relatively fragile, the resulting bonding layer is fractionally-releasable, as discussed above with reference to FIG. 3.

It has been found that either a siliconized or non-siliconized support sheet can be used with satisfactory results in the above spray methods. Specifically, both Polyester 770 manufactured by and available from DuPont Corporation (a non-siliconized, non-coronized polyester film having an anti-static coating) and T-90 manufactured by and available from CPFilms, Inc. (a siliconized polyester film) have been tested with satisfactory results. In the preferred embodiment, however, the siliconized support sheet is preferred slightly to the non-siliconized support sheet for the above spray methods.

In applications where the bonding layer solution is sprayed onto the surface of the support sheet to create the micro-dot pattern discussed above, it has been found that the bonding layer solution preferably further comprises a plasticizer, which increases the surface tension of the bonding layer solution and thereby helps the discontinuous micro-dot pattern to form without reducing the bonding layer solution to a thin-film coating.

The plasticizer is preferably compatible with the bonding agent. In the preferred embodiment, the plasticizer is BENZOFLEX 50, manufactured by and available from Velsicol Chemical Corporation, of Rosemont, Ill. The use of other plasticizers, either in addition to or in lieu of BENZOFLEX 50, will be apparent to one skilled in the art having knowledge of the present specification.

It has been found that the amount of plasticizer added to the bonding layer solution to assist in the formation of the micro-dot pattern is preferably from about 0.5% to about 5% of the bonding agent by weight, more preferably from about 1% to about 3% of the bonding agent by weight, and most preferably about 2% of the bonding agent by weight. For example, where the total weight of the bonding agent is 80 grams, the amount of plasticizer added to the bonding layer solution is preferably from about 0.4 to about 4 grams, more preferably from about 0.8 to about 2.4 grams, and most preferably from about 1.6 grams. Other ratios will be apparent to one skilled in the art having knowledge of the present specification.

Turning now to FIG. 4, an embodiment for a preferred curtain coating method is illustrated, and preferably comprises master roll 402 around which support sheet 102 is wound, the leading terminal edge of which is conveyed and continuously fed to master roll 410 via tensioning and positioning rollers 404, 406 and 408.

The bonding layer solution, located in reservoir 412, is gravity fed to spray delivery tube 414, which is preferably a longitudinal tube spanning at least the width of support sheet 102 and comprises a plurality of holes located along the bottom thereof which individually release the bonding solution onto and along the width of roller 406, preferably in excess to form a pool thereof within well area 416.

A portion of the bonding layer solution located within well area 416 coats the top surface of support sheet 102 as it travels vertically toward roller 408, where the evaporation process of the bonding layer solution is preferably accelerated via fan 418.

Any excess bonding layer solution which drips off either of the longitudinal edges of support sheet 102 into containment chamber 420 is preferably recycled back into reservoir 412 by conventional method (not shown).

It has been found that either a siliconized or non-siliconized support sheet can be used with satisfactory results in the above curtain coating process. Specifically, both Polyester 770 manufactured by and available from DuPont Corporation (a non-siliconized, non-coronized polyester film having an anti-static coating) and T-90 manufactured by and available from CPFilms, Inc. (a siliconized polyester film) have been tested with satisfactory results. In the preferred embodiment, however, the non-siliconized support sheet is preferred slightly to the siliconized support sheet for the above curtain coating process.

Other embodiments for curtain coating, as well as other embodiments for applying the bonding layer solution to the surface of the support sheet, will be apparent to one skilled in the art having knowledge of the present specification.

The goal of the above-described curtain coating method is to lay down a relatively fine, thin-film layer of bonding layer solution such that, upon evaporation thereof, the resulting bonding layer is a relatively fragile, thin film, preferably having a thickness from about 0.004 mils to about 0.5 mils, more preferably from about 0.02 mils to about 0.25 mils, and most preferably from about 0.1 mils to about 0.2 mils. Since the desired thin-film layer is relatively fragile, the resulting bonding layer is fractionally-releasable, as discussed above with reference to FIG. 3.

In summary, when the bonding layer solution is applied in a discontinuous pattern, for example, via the spray process described above, it is preferably applied to the support sheet in a dense micro-dot pattern which, by its very nature of being discontinuous, yields the desired fractionally-releasable properties discussed above with reference to FIG. 3.

When the bonding layer solution is applied as a continuous layer, for example, via the spray or curtain coating process described above, it is preferably applied to the support sheet in a sufficiently thin layer which, by virtue of the fragile nature of such a thin layer, yields the desired fractionally-releasable properties discussed above with reference to FIG. 3.

Guided by the present specification, one skilled in the art could determine appropriate and possibly different concentrations and/or ratios of~the bonding agent and/or carrier agent components, or otherwise adjust various controllable system parameters (e.g., nozzle configuration or distance of spray nozzle from support sheet in spray method, line speed of support sheet, depth of well area, volume output from spray delivery tube or vertical/horizontal line configuration in the curtain coating process) when applying the teachings of the present specification to other types of application equipment and/or methods to obtain the desired fractionally-releasable properties, all without undue experimentation.

Remaining after the bonding layer solution has been applied to the top surface of the support sheet, whether by spray, curtain coating or otherwise, and the carrier agent has fully evaporated, is fractionally-releasable bonding layer 106, which is preferably adhered to the surface of the support sheet. Thereafter, the layer of polymer resin composition 104 can be applied thereto, in any conventional manner.

Bonding layer 106, prior to the application of polymer resin composition 104, is subject to oxidative degradation in the presence of sunlight or other sources of ultraviolet radiation, as well as elevated temperatures.

Accordingly, where the intermediate product comprising the support sheet and bonding layer will be stored for an extended period of time or subjected to ultraviolet radiation and/or elevated temperatures prior to the application of the polymer resin composition, or where the resulting bonding layer is applied as a thin film (i.e., via continuous spray process or curtain coating), it is preferable that the bonding layer be fortified with an antioxidant and, optionally, a light absorber (also referred to as an actinic radiation blocker).

Given the negative effects of oxidation, it is preferable that the bonding layer generally be fortified with an antioxidant, preferably by adding the antioxidant to the bonding layer solution.

Examples of antioxidants include Pentaphen 67 (para-tert-amylphenol), BHT (2,6-di-tert-butyl-para-cresol), Antioxidant 2246 [2,3-methylene bis (4-methyl-6-tert-butyl)phenol] available from ISP of Wayne, N.J., and INION, available from Shell Chemical Company, of Wilmington, Del. In the preferred embodiment, the antioxidant is INION. The use of other antioxidants, either in addition to or in lieu of INION, will be apparent to one skilled in the art having knowledge of the present specification.

In the preferred embodiment, the amount of antioxidant added to the bonding layer solution is from about 0.1% to about 4% of the bonding agent by weight, more preferably from about 0.5% to about 2% of the bonding agent by weight, and most preferably from about 1% to about 1.5% of the bonding agent by weight. Other percentages will be apparent to one skilled in the art having knowledge of the present specification, and will also be directly proportional to the length of time the product, or intermediate product, will be stored before being used, since the preferred support sheets are typically gas-permeable.

Examples of light absorbers include 2,4-dihydroxbenzophenone. The use of other light absorbers, either in addition to or in lieu of 2,4-dihydroxbenzophenone, will be apparent to one skilled in the art having knowledge of the present specification.

In the preferred embodiment, the amount of light absorber added to the bonding layer solution is from about 0.1% to about 0.5% of the bonding agent by weight. Other percentages will be apparent to one skilled in the art having knowledge of the present specification.

The addition of a light absorber to the bonding layer is optional, especially where a light absorber has been added to the support sheet, as discussed in more detail hereinbelow.

The preferred embodiments of the polyester film support sheet discussed above are typically substantially transparent, allowing actinic radiation to pass therethrough. Accordingly, and as discussed in more detail below after the following Examples, the support sheet can be manufactured to be either substantially opaque or comprise an actinic radiation blocker to reduce the effects of accidental actinic radiation exposure of the polymer resin composition through the support sheet.

### EXAMPLE 1

A bonding layer solution was prepared as follows. The bonding agent comprising 80 grams of ETHOCELL STD-10 ethylcellulose was added to 700 grams of toluene, and periodically agitated for about 1 hour to allow the ETHOCELL STD-10 to completely dissolve therein. Thereafter, 300 rams of ethyl alcohol was slowly added therein while mixing, to prevent shocking the mixture. Finally, 0.4 grams of INION antioxidant was admixed therein.

Thereafter, the bonding layer solution was sprayed onto a support sheet of T-90 silicone-impregnated polyester film having an overall thickness of about 3 mils using a Sada Jet Model J pressurized spray gun, at 45 psi, with a 0.67 cfm nozzle substantially opened to produce a fan-shaped spray pattern. The nozzle was located about 12-14 inches away from the surface of the support sheet using a 50% overlapping spray pattern.

This produced a pattern on the support sheet which can be described as a dense random micro-dot pattern such that the micro-dots were located in very close proximity to each other, some of which were overlapping, some of which were not overlapping.

Warm air was passed over the support sheet for about 3 minutes to speed the drying of the bonding layer solution. Thereafter, observation revealed a randomized micro-dot, discontinuous pattern of ethylcellulose on the support sheet having an average thickness of approximately 0.5 mils with variations ranging from about 0.1 mils to about 1.25 mils.

The support sheet comprising the bonding layer was rolled up onto a master roll, and trucked to a separate location for the application of the polymer resin composition having photocrosslinkability.

An extruder/coater applied two uniform layers of QTX water-soluble polymer resin composition having photocrosslinkability onto the surface of the bonding layer. After the application of each layer, the laminate film was passed through an oven set at about 180° F. for about 20 minutes to dry the polymer resin composition, which was then allowed to cool to room temperature. The overall thickness of the polymer resin composition after the application of two layers was about 3.5 mil. The finished photo-sensitive laminate film was then rolled up onto a master roll.

A rectangular piece was subsequently cut from the photo-sensitive laminate film, a positive image generated by a laser printer onto a transparent film having opaque portions (i.e., the positive image) and transparent portions was placed image-side down on the surface of the layer of polymer resin composition, and a small sheet of glass was placed thereover to insure uniform contact. The positive image was exposed to a source of actinic radiation, specifically, a 250 watt, mercury vapor lamp at a distance of 18 inches for approximately 60 seconds.

The photo-sensitive laminate film was then developed under controlled, low-light conditions using a mist of water emitted from a spray nozzle attached to a standard household garden hose for approximately 60 seconds, washing away the unexposed, non-crosslinked areas of the polymer resin composition, leaving an image mask configured as the negative of the image.

After the image mask was allowed to dry thoroughly, a high-tack, water-redispersible pressure-sensitive adhesive, specifically, RZ-2 Adhesive available from Rayzist Photomasks, Inc., of Vista, Calif., was applied in a thin layer onto a flat glass substrate and allowed to dry for about 5 minutes. Thereafter, the image mask was applied to the layer of adhesive, polymer resin composition-side down, and the support sheet was removed therefrom.

Inspection revealed that the portion of the fractionally-releasable bonding layer previously located between the support sheet and the image mask was substantially transferred to the image mask, while the remaining portion of the fractionally-releasable bonding layer remained adhered to the support sheet.

In some instances, the adhesive located on the substrate contacted a portion of the bonding layer located on the support sheet, causing some of the bonding layer to transfer to the adhesive. This transfer can be minimized with increased thickness in the polymer resin composition from which the image mask is created.

Regardless, the transfer of the bonding layer to the adhesive did not affect the Example in any adverse manner, and is not considered by the inventors to vitiate the above statement that “the portion of the fractionally-releasable bonding layer located between the support sheet and the image mask was substantially transferred to the image mask, while the remaining portion of the fractionally-releasable bonding layer remained adhered to the support sheet”, since the transfer thereof was a result of contact with the adhesive and not a result of being retained by the image mask itself during the transfer process.

The flat glass substrate was then sandblasted using 180 grit aluminum oxide blast media in a pressure pot sandblaster at an operating pressure of about 20 psi held approximately 3 inches from the surface of the substrate for about 30 seconds. The image mask was then removed by submersion in water which dissolved the adhesive, and the flat glass was then dried and cleaned using a common household glass cleaner. Observation revealed an etched pattern on the surface of the flat glass substrate identical to the positive image.

A second test was run, as above, with the exception that a chemical etching solution was used in lieu of sandblasting. Specifically, the chemical etching solution was ARMOUR ETCH, an acid-based etching creme available from Armour Products of Wykoff, N.J., which was applied to the glass substrate within the open areas of the image mask for a period of about 1 minute, and then washed under a continuous flow of water to remove all traces of the chemical etching solution, image mask and adhesive. Observation revealed an etched pattern on the surface of the flat glass substrate identical to the positive image.

### EXAMPLES 2-17

| | Bonding Agent | Carrier Agent | |
|---|---|---|---|
| Example | Ethylcellulose | Toluene/Ethyl Alcohol | Application |
| 2 | 60 grams | 1000 grams/0 grams | spray |
| 3 | 50 grams | ″ | ″ |
| 4 | 40 grams | ″ | ″ |
| 5 | 30 grams | ″ | ″ |
| 6 | 25 grams | ″ | ″ |
| 7 | 20 grams | ″ | ″ |
| 8 | 20 grams | 1000 grams/0 grams | coating |
| 9 | 15 grams | ″ | ″ |
| 10 | 13 grams | ″ | ″ |
| 11 | 12 grams | ″ | ″ |
| 12 | 10 grams | ″ | ″ |
| 13 | 9 grams | ″ | ″ |
| 14 | 8 grams | ″ | ″ |
| 15 | 7 grams | ″ | ″ |
| 16 | 6 grams | ″ | ″ |
| 17 | 5 grams | ″ | ″ |

Examples 2-7 are identical to Example 1 above, with the exception of the composition of the carrier agent and the amount of bonding agent added thereto, with satisfactory results. It was found that ethylcellulose concentrations above about 60 grams resulted in a bonding layer solution which was too thick to be sprayed using the Sada Jet Model J pressurized spray gun, as configured above. It was also found that ethylcellulose concentrations below about 20 grams resulted in a bonding layer solution which did not deposit a subjectively sufficient amount of ethylcellulose onto the support sheet to make the spray process advantageous.

Specifically, the support sheet was unevenly coated and, where coated, the resulting bonding layer was too thin to be operable. This situation could have been and was rectified by multiple passes of the spray gun to deposit sufficient ethylcellulose thereon. However, the inventors believe that the multiple passes of the spray gun renders the spraying process inefficient from a production standpoint for ethylcellulose concentrations below about 20 grams, and therefore not advantageous.

In Examples 8-17, the bonding layer solution was applied via the curtain coating method described above with reference to FIG. 4, to both a T-90 siliconized polyester support sheet, as well as to a Polyester 770 non-siliconized polyester support sheet, with satisfactory results. It was found that ethylcellulose concentrations above about 20 grams resulted in a bonding layer which was, in some portions, less fractionable than desired.

Specifically, inspection of the image mask after the support sheet was removed revealed an occasional bonding layer bridge between extremely fine details of the image mask, i.e., details spaced about 60 microns apart. The occurrence of this type of bonding layer bridge became more prevalent with increased ethylcellulose concentrations above about 20 grams.

The minor occurrence of bonding layer bridges are not considered to be inoperative or in any way defective Examples. Bonding layer bridges are easily removed by either sandblasting or the application of a chemical etching solution, with no adverse result to the image etched onto the substrate.

However, the excessive occurrence of bonding layer bridges are not considered by the inventors to be desirable, especially where the user will etch the substrate using a chemical etching solution, since removal of numerous bonding layer bridges will require additional etching solution, and may require at least some additional time therefor.

It was also found that ethylcellulose concentrations below about 5 grams resulted in an inadequate bonding layer, i.e., the resulting bonding layer was too thin and the coverage thereof too sporadic to be of practical use.

### EXAMPLES 18-33

| | Bonding Agent | Carrier Agent | |
|---|---|---|---|
| Example | Ethylcellulose | Toluene/Ethyl Alcohol | Application |
| 18 | 70 grams | 950 grams/50 grams | spray |
| 19 | 60 grams | ″ | ″ |
| 20 | 50 grams | ″ | ″ |
| 21 | 40 grams | ″ | ″ |
| 22 | 35 grams | ″ | ″ |
| 23 | 25 grams | ″ | ″ |
| 24 | 20 grams | ″ | ″ |
| 25 | 20 grams | 950 grams/50 grams | coating |
| 26 | 15 grams | ″ | ″ |
| 27 | 13 grams | ″ | ″ |
| 28 | 12 grams | ″ | ″ |
| 29 | 10 grams | ″ | ″ |
| 30 | 9 grams | ″ | ″ |
| 31 | 8 grams | ″ | ″ |
| 32 | 7 grams | ″ | ″ |
| 33 | 6 grams | ″ | ″ |

Examples 18-24 are identical to Example 1 above, with the exception of the composition of the carrier agent and the amount of bonding agent added thereto, with satisfactory results. It was found that ethylcellulose concentrations above about 70 grams resulted in a bonding layer solution which was too thick to be sprayed using the Sada Jet Model J pressurized spray gun, as configured above. It was also found that ethylcellulose concentrations below about 20 grams resulted in a bonding layer solution which did not deposit a subjectively sufficient amount of ethylcellulose onto the support sheet to make the spray process advantageous, as discussed above with reference to Examples 2-7.

Examples 25-33 are identical to Examples 8-17 above, with the exception of the composition of the carrier agent and the amount of bonding agent added thereto, with satisfactory results. It was found that ethylcellulose concentrations above about 20 grams resulted in a bonding layer which was, in some portions, less fractionable than desired, as discussed above with reference to Examples 8-17.

It was also found that ethylcellulose concentrations below about 6 grams resulted in a cloudy bonding layer solution, i.e., the resulting bonding layer solution contained too high a concentration of ethyl alcohol for the amount of ethylcellulose, which adversely affected the ethylcellulose in the bonding layer solution and rendered the resulting bonding layer unusable.

### EXAMPLES 34-45

| | Bonding Agent | Carrier Agent | |
|---|---|---|---|
| Example | Ethylcellulose | Toluene/Ethyl Alcohol | Application |
| 34 | 90 grams | 875 grams/125 grams | spray |
| 35 | 80 grams | ″ | ″ |
| 36 | 70 grams | ″ | ″ |
| 37 | 60 grams | ″ | ″ |
| 38 | 50 grams | ″ | ″ |
| 39 | 40 grams | ″ | ″ |
| 40 | 30 grams | ″ | ″ |
| 41 | 25 grams | ″ | ″ |
| 42 | 20 grams | 875 grams/125 grams | coating |
| 43 | 15 grams | ″ | ″ |
| 44 | 13 grams | ″ | ″ |
| 45 | 12 grams | ″ | ″ |

Examples 34-41 are identical to Example 1 above, with the exception of the composition of the carrier agent and the amount of bonding agent added thereto, with satisfactory results. It was found that ethylcellulose concentrations above about 90 grams resulted in a bonding layer solution which was too thick to be sprayed using the Sada Jet Model J pressurized spray gun, as configured above. It was also found that ethylcellulose concentrations below about 25 grams resulted in a bonding layer solution which did not deposit a subjectively sufficient amount of ethylcellulose onto the support sheet to make the spray process advantageous, as discussed above with reference to Examples 2-7.

Examples 42-45 are identical to Examples 8-17 above, with the exception of the composition of the carrier agent and the amount of bonding agent added thereto, with satisfactory results. It was found that ethylcellulose concentrations above about 20 grams resulted in a bonding layer which was, in some portions, less fractionable than desired, as discussed above with reference to Examples 8-17. It was also found that ethylcellulose concentrations below about 12 grams resulted in an inadequate bonding layer, as discussed above with reference to Examples 25-33.

### EXAMPLES 46-59

| | Bonding Agent | Carrier Agent | |
|---|---|---|---|
| Example | Ethylcellulose | Toluene/Ethyl Alcohol | Application |
| 46 | 140 grams | 850 grams/150 grams | spray |
| 47 | 130 grams | ″ | ″ |
| 48 | 120 grams | ″ | ″ |
| 49 | 110 grams | ″ | ″ |
| 50 | 100 grams | ″ | ″ |
| 51 | 90 grams | ″ | ″ |
| 52 | 80 grams | ″ | ″ |
| 53 | 70 grams | ″ | ″ |
| 54 | 60 grams | ″ | ″ |
| 55 | 50 grams | ″ | ″ |
| 56 | 40 grams | ″ | ″ |
| 57 | 30 grams | ″ | ″ |
| 58 | 25 grams | ″ | ″ |
| 59 | 20 grams | ″ | ″ |

Examples 46-59 are identical to Example 1 above, with the exception of the composition of the carrier agent and the amount of bonding agent added thereto, with satisfactory results. It was found that ethylcellulose concentrations above about 140 grams resulted in a bonding layer solution which was too thick to be sprayed using the Sada Jet Model J pressurized spray gun, as configured above. It was also found that ethylcellulose concentrations below about 20 grams resulted in an unusable bonding layer solution, as discussed above with reference to Examples 2-7.

### EXAMPLES 60-73

| | Bonding Agent | Carrier Agent | |
|---|---|---|---|
| Example | Ethylcellulose | Toluene/Ethyl Alcohol | Application |
| 60 | 140 grams | 825 grams/175 grams | spray |
| 61 | 130 grams | ″ | ″ |
| 62 | 120 grams | ″ | ″ |
| 63 | 110 grams | ″ | ″ |
| 64 | 100 grams | ″ | ″ |
| 65 | 90 grams | ″ | ″ |
| 66 | 80 grams | ″ | ″ |
| 67 | 70 grams | ″ | ″ |
| 68 | 60 grams | ″ | ″ |
| 69 | 50 grams | ″ | ″ |
| 70 | 40 grams | ″ | ″ |
| 71 | 30 grams | ″ | ″ |
| 72 | 25 grams | ″ | ″ |
| 73 | 20 grams | ″ | ″ |

Examples 60-73 are identical to Example 1 above, with the exception of the composition of the carrier agent and the amount of bonding agent added thereto, with satisfactory results. It was found that ethylcellulose concentrations above about 140 grams resulted in a bonding layer solution which was too thick to be sprayed using the Sada Jet Model J pressurized spray gun, as configured above. It was also found that ethylcellulose concentrations below about 20 grams resulted in an unusable bonding layer solution, as discussed above with reference to Examples 2-7.

### EXAMPLES 74-89

| | Bonding Agent | Carrier Agent | |
|---|---|---|---|
| Example | Ethylcellulose | Toluene/Ethyl Alcohol | Application |
| 74 | 160 grams | 800 grams/200 grams | spray |
| 75 | 150 grams | ″ | ″ |
| 76 | 140 grams | ″ | ″ |
| 77 | 130 grams | ″ | ″ |
| 78 | 120 grams | ″ | ″ |
| 79 | 110 grams | ″ | ″ |
| 80 | 100 grams | ″ | ″ |
| 81 | 90 grams | ″ | ″ |
| 82 | 80 grams | ″ | ″ |
| 83 | 70 grams | ″ | ″ |
| 84 | 60 grams | ″ | ″ |
| 85 | 50 grams | ″ | ″ |
| 86 | 40 grams | ″ | ″ |
| 87 | 30 grams | ″ | ″ |
| 88 | 25 grams | ″ | ″ |
| 89 | 20 grams | ″ | ″ |

Examples 74-89 are identical to Example 1 above, with the exception of the composition of the carrier agent and the amount of bonding agent added thereto, with satisfactory results. It was found that ethylcellulose concentrations above about 160 grams resulted in a bonding layer solution which was too thick to be sprayed using the Sada Jet Model J pressurized spray gun, as configured above. It was also found that ethylcellulose concentrations below about 20 grams resulted in an unusable bonding layer solution, as discussed above with reference to Examples 25-33.

### EXAMPLES 90-103

| | Bonding Agent | Carrier Agent | |
|---|---|---|---|
| Example | Ethylcellulose | Toluene/Ethyl Alcohol | Application |
| 90 | 140 grams | 775 grams/225 grams | spray |
| 91 | 130 grams | ″ | ″ |
| 92 | 120 grams | ″ | ″ |
| 93 | 110 grams | ″ | ″ |
| 94 | 100 grams | ″ | ″ |
| 95 | 90 grams | ″ | ″ |
| 96 | 80 grams | ″ | ″ |
| 97 | 70 grams | ″ | ″ |
| 98 | 60 grams | ″ | ″ |
| 99 | 50 grams | ″ | ″ |
| 100 | 40 grams | ″ | ″ |
| 101 | 30 grams | ″ | ″ |
| 102 | 25 grams | ″ | ″ |
| 103 | 20 grams | ″ | ″ |

Examples 90-103 are identical to Example 1 above, with the exception of the composition of the carrier agent and the amount of bonding agent added thereto, with satisfactory results. It was found that ethylcellulose concentrations above about 140 grams resulted in a bonding layer solution which was too thick to be sprayed using the Sada Jet Model J pressurized spray gun, as configured above. It was also found that ethylcellulose concentrations below about 20 grams resulted in an unusable bonding layer solution, as discussed above with reference to Examples 25-33.

### EXAMPLES 104-112

| | Bonding Agent | Carrier Agent | |
|---|---|---|---|
| Example | Ethylcellulose | Toluene/Ethyl Alcohol | Application |
| 104 | 150 grams | 750 grams/250 grams | spray |
| 105 | 140 grams | ″ | ″ |
| 106 | 130 grams | ″ | ″ |
| 107 | 120 grams | ″ | ″ |
| 108 | 110 grams | ″ | ″ |
| 109 | 100 grams | ″ | ″ |
| 110 | 90 grams | ″ | ″ |
| 111 | 80 grams | ″ | ″ |
| 112 | 70 grams | ″ | ″ |

Examples 104-112 are identical to Example 1 above, with the exception of the composition of the carrier agent and the amount of bonding agent added thereto, with satisfactory results. It was found that ethylcellulose concentrations above about 150 grams resulted in a bonding layer solution which was too thick to be sprayed using the Sada Jet Model J pressurized spray gun, as configured above. It was also found that ethylcellulose concentrations below about 70 grams resulted in an unusable bonding layer solution, as discussed above with reference to Examples 25-33.

### EXAMPLES 113-121

| | Bonding Agent | Carrier Agent | |
|---|---|---|---|
| Example | Ethylcellulose | Toluene/Ethyl Alcohol | Application |
| 113 | 140 grams | 725 grams/275 grams | spray |
| 114 | 130 grams | ″ | ″ |
| 115 | 120 grams | ″ | ″ |
| 116 | 110 grams | ″ | ″ |
| 117 | 100 grams | ″ | ″ |
| 118 | 90 grams | ″ | ″ |
| 119 | 80 grams | ″ | ″ |
| 120 | 70 grams | ″ | ″ |
| 121 | 60 grams | ″ | ″ |

Examples 113-121 are identical to Example 1 above, with the exception of the composition of the carrier agent and the amount of bonding agent added thereto, with satisfactory results. It was found that ethylcellulose concentrations above about 140 grams resulted in a bonding layer solution which was too thick to be sprayed using the Sada Jet Model J pressurized spray gun, as configured above. It was also found that ethylcellulose concentrations below about 60 grams resulted in an unusable bonding layer solution, as discussed above with reference to Examples 25-33.

### EXAMPLES 122-128

| | Bonding Agent | Carrier Agent | |
|---|---|---|---|
| Example | Ethylcellulose | Toluene/Ethyl Alcohol | Application |
| 122 | 130 grams | 700 grams/300 grams | spray |
| 123 | 120 grams | ″ | ″ |
| 124 | 110 grams | ″ | ″ |
| 125 | 100 grams | ″ | ″ |
| 126 | 90 grams | ″ | ″ |
| 127 | 80 grams | ″ | ″ |
| 128 | 70 grams | ″ | ″ |

Examples 122-128 are identical to Example 1 above, with the exception of the composition of the carrier agent and the amount of bonding agent added thereto, with satisfactory results. It was found that ethylcellulose concentrations above about 130 grams resulted in a bonding layer solution which was too thick to be sprayed using the Sada Jet Model J pressurized spray gun, as configured above. It was also found that ethylcellulose concentrations below about 70 grams resulted in an unusable bonding layer solution, as discussed above with reference to Examples 25-33.

### EXAMPLES 129-135

| | Bonding Agent | Carrier Agent | |
|---|---|---|---|
| Example | Ethylcellulose | Toluene/Ethyl Alcohol | Application |
| 129 | 140 grams | 675 grams/325 grams | spray |
| 130 | 130 grams | ″ | ″ |
| 131 | 120 grams | ″ | ″ |
| 132 | 110 grams | ″ | ″ |
| 133 | 100 grams | ″ | ″ |
| 134 | 90 grams | ″ | ″ |
| 135 | 80 grams | ″ | ″ |

Examples 129-135 are identical to Example 1 above, with the exception of the composition of the carrier agent and the amount of bonding agent added thereto, with satisfactory results. It was found that ethylcellulose concentrations above about 140 grams resulted in a bonding layer solution which was too thick to be sprayed using the Sada Jet Model J pressurized spray gun, as configured above. It was also found that ethylcellulose concentrations below about 80 grams resulted in an unusable bonding layer solution, as discussed above with reference to Examples 25-33.

### EXAMPLES 136-144

| | Bonding Agent | Carrier Agent | |
|---|---|---|---|
| Example | Ethylcellulose | Toluene/Ethyl Alcohol | Application |
| 136 | 150 grams | 650 grams/350 grams | spray |
| 137 | 140 grams | ″ | ″ |
| 138 | 130 grams | ″ | ″ |
| 139 | 120 grams | ″ | ″ |
| 140 | 110 grams | ″ | ″ |
| 141 | 100 grams | ″ | ″ |
| 142 | 90 grams | ″ | ″ |
| 143 | 80 grams | ″ | ″ |
| 144 | 70 grams | ″ | ″ |

Examples 136-144 are identical to Example 1 above, with the exception of the composition of the carrier agent and the amount of bonding agent added thereto, with satisfactory results. It was found that ethylcellulose concentrations above about 150 grams resulted in a bonding layer solution which was too thick to be sprayed using the Sada Jet Model J pressurized spray gun, as configured above. It was also found that ethylcellulose concentrations below about 70 grams resulted in an unusable bonding layer solution, as discussed above with reference to Examples 25-33.

### EXAMPLES 145-155

| | Bonding Agent | Carrier Agent | |
|---|---|---|---|
| Example | Ethylcellulose | Toluene/Ethyl Alcohol | Application |
| 145 | 170 grams | 625 grams/375 grams | spray |
| 146 | 160 grams | ″ | ″ |
| 147 | 150 grams | ″ | ″ |
| 148 | 140 grams | ″ | ″ |
| 149 | 130 grams | ″ | ″ |
| 150 | 120 grams | ″ | ″ |
| 151 | 110 grams | ″ | ″ |
| 152 | 100 grams | ″ | ″ |
| 153 | 90 grams | ″ | ″ |
| 154 | 80 grams | ″ | ″ |
| 155 | 70 grams | ″ | ″ |

Examples 145-155 are identical to Example 1 above, with the exception of the composition of the carrier agent and the amount of bonding agent added thereto, with satisfactory results. It was found that ethylcellulose concentrations above about 170 grams resulted in a bonding layer solution which was too thick to be sprayed using the Sada Jet Model J pressurized spray gun, as configured above. It was also found that ethylcellulose concentrations below about 70 grams resulted in an unusable bonding layer solution, as discussed above with reference to Examples 25-33.

### EXAMPLES 156-164

| | Bonding Agent | Carrier Agent | |
|---|---|---|---|
| Example | Ethylcellulose | Toluene/Ethyl Alcohol | Application |
| 156 | 160 grams | 600 grams/400 grams | spray |
| 157 | 150 grams | ″ | ″ |
| 158 | 140 grams | ″ | ″ |
| 159 | 130 grams | ″ | ″ |
| 160 | 120 grams | ″ | ″ |
| 161 | 110 grams | ″ | ″ |
| 162 | 100 grams | ″ | ″ |
| 163 | 90 grams | ″ | ″ |
| 164 | 80 grams | ″ | ″ |

Examples 156-164 are identical to Example 1 above, with the exception of the composition of the carrier agent and the amount of bonding agent added thereto, with satisfactory results. It was found that ethylcellulose concentrations above about 160 grams resulted in a bonding layer solution which was too thick to be sprayed using the Sada Jet Model J pressurized spray gun, as configured above. It was also found that ethylcellulose concentrations below about 80 grams resulted in an unusable bonding layer solution, as discussed above with reference to Examples 25-33.

### EXAMPLES 165-179

| | Bonding Agent | Carrier Agent | |
|---|---|---|---|
| Example | Polyvinyl Acetate | Toluene/Ethyl Alcohol | Application |
| 165 | 130 grams | 999 grams/1 gram | spray |
| 166 | 120 grams | ″ | ″ |
| 167 | 110 grams | ″ | ″ |
| 168 | 100 grams | ″ | ″ |
| 169 | 90 grams | ″ | ″ |
| 170 | 80 grams | ″ | ″ |
| 171 | 70 grams | ″ | ″ |
| 172 | 60 grams | ″ | ″ |
| 173 | 70 grams | 999 grams/1 gram | coating |
| 174 | 60 grams | ″ | ″ |
| 175 | 50 grams | ″ | ″ |
| 176 | 40 grams | ″ | ″ |
| 177 | 30 grams | ″ | ″ |
| 178 | 25 grams | ″ | ″ |
| 179 | 20 grams | ″ | ″ |

Examples 165-172 are identical to Example 1 above, with the exception of the composition of the bonding agent (polyvinyl acetate in lieu of ethylcellulose), the composition of the carrier agent, and the amount of bonding agent added thereto, with satisfactory results. It was found that polyvinyl acetate concentrations above about 130 grams resulted in a bonding layer solution which was too thick to be sprayed using the Sada Jet Model J pressurized spray gun, as configured above. It was also found that polyvinyl acetate concentrations below about 60 grams resulted in a bonding layer solution which did not deposit a subjectively sufficient amount of polyvinyl acetate onto the support sheet to make the spray process advantageous, as discussed above with reference to Examples 2-7.

Examples 173-179 are identical to Examples 8-17 above, with the exception of the composition of the bonding agent (polyvinyl acetate in lieu of ethylcellulose), the composition of the carrier agent, and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, i.e., the support sheet was unevenly coated and, where coated, the resulting bonding layer was too thin to be operable.

### EXAMPLES 180-194

| | Bonding Agent | Carrier Agent | |
|---|---|---|---|
| Example | Polyvinyl Acetate | Toluene/Ethyl Alcohol | Application |
| 180 | 130 grams | 975 grams/25 grams | spray |
| 181 | 120 grams | ″ | ″ |
| 182 | 110 grams | ″ | ″ |
| 183 | 100 grams | ″ | ″ |
| 184 | 90 grams | ″ | ″ |
| 185 | 80 grams | ″ | ″ |
| 186 | 70 grams | ″ | ″ |
| 187 | 60 grams | ″ | ″ |
| 188 | 70 grams | 975 grams/25 grams | coating |
| 189 | 60 grams | ″ | ″ |
| 190 | 50 grams | ″ | ″ |
| 191 | 40 grams | ″ | ″ |
| 192 | 30 grams | ″ | ″ |
| 193 | 25 grams | ″ | ″ |
| 194 | 20 grams | ″ | ″ |

Examples 180-187 are identical to Examples 165-172 above, with the exception of the composition of the carrier agent, and the amount of bonding agent added thereto, with satisfactory results. It was found that polyvinyl acetate concentrations above about 130 grams resulted in a bonding layer solution which was too thick to be sprayed using the Sada Jet Model J pressurized spray gun, as configured above. It was also found that polyvinyl acetate concentrations below about 60 grams resulted in a bonding layer solution which did not deposit a subjectively sufficient amount of polyvinyl acetate onto the support sheet to make the spray process advantageous, as discussed above with reference to Examples 2-7.

Examples 188-194 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 173-179.

### EXAMPLES 195-210

| | Bonding Agent | Carrier Agent | |
|---|---|---|---|
| Example | Polyvinyl Acetate | Toluene/Ethyl Alcohol | Application |
| 195 | 130 grams | 950 grams/50 grams | spray |
| 196 | 120 grams | ″ | ″ |
| 197 | 110 grams | ″ | ″ |
| 198 | 100 grams | ″ | ″ |
| 199 | 90 grams | ″ | ″ |
| 200 | 80 grams | ″ | ″ |
| 201 | 70 grams | ″ | ″ |
| 202 | 60 grams | ″ | ″ |
| 203 | 50 grams | ″ | ″ |
| 204 | 70 grams | 950 grams/50 grams | coating |
| 205 | 60 grams | ″ | ″ |
| 206 | 50 grams | ″ | ″ |
| 207 | 40 grams | ″ | ″ |
| 208 | 30 grams | ″ | ″ |
| 209 | 25 grams | ″ | ″ |
| 210 | 20 grams | ″ | ″ |

Examples 195-203 are identical to Examples 165-172 above, with the exception of the composition of the carrier agent, and the amount of bonding agent added thereto, with satisfactory results. It was found that polyvinyl acetate concentrations above about 130 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 204-210 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 173-179.

### EXAMPLES 211-226

| | Bonding Agent | Carrier Agent | |
|---|---|---|---|
| Example | Polyvinyl Acetate | Toluene/Ethyl Alcohol | Application |
| 211 | 140 grams | 925 grams/75 grams | spray |
| 212 | 130 grams | ″ | ″ |
| 213 | 120 grams | ″ | ″ |
| 214 | 110 grams | ″ | ″ |
| 215 | 100 grams | ″ | ″ |
| 216 | 90 grams | ″ | ″ |
| 217 | 80 grams | ″ | ″ |
| 218 | 70 grams | ″ | ″ |
| 219 | 60 grams | ″ | ″ |
| 220 | 70 grams | 925 grams/75 grams | coating |
| 221 | 60 grams | ″ | ″ |
| 222 | 50 grams | ″ | ″ |
| 223 | 40 grams | ″ | ″ |
| 224 | 30 grams | ″ | ″ |
| 225 | 25 grams | ″ | ″ |
| 226 | 20 grams | ″ | ″ |

Examples 211-219 are identical to Examples 165-172 above, with the exception of the composition of the carrier agent, and the amount of bonding agent added thereto, with satisfactory results. It was found that polyvinyl acetate concentrations above about 140 grams resulted in a bonding layer solution which was too thick to be sprayed using the Sada Jet Model J pressurized spray gun, as configured above. It was also found that polyvinyl acetate concentrations below about 60 grams resulted in a bonding layer solution which did not deposit a subjectively sufficient amount of polyvinyl acetate onto the support sheet to make the spray process advantageous, as discussed above with reference to Examples 2-7.

Examples 220-226 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 173-179.

### EXAMPLES 227-241

| | Bonding Agent | Carrier Agent | |
|---|---|---|---|
| Example | Polyvinyl Acetate | Toluene/Ethyl Alcohol | Application |
| 227 | 130 grams | 900 grams/100 grams | spray |
| 228 | 120 grams | ″ | ″ |
| 229 | 110 grams | ″ | ″ |
| 230 | 100 grams | ″ | ″ |
| 231 | 90 grams | ″ | ″ |
| 232 | 80 grams | ″ | ″ |
| 233 | 70 grams | ″ | ″ |
| 234 | 60 grams | ″ | ″ |
| 235 | 50 grams | ″ | ″ |
| 236 | 60 grams | 900 grams/100 grams | coating |
| 237 | 50 grams | ″ | ″ |
| 238 | 40 grams | ″ | ″ |
| 239 | 30 grams | ″ | ″ |
| 240 | 25 grams | ″ | ″ |
| 241 | 20 grams | ″ | ″ |

Examples 227-235 are identical to Examples 165-172 above, with the exception of the composition of the carrier agent, and the amount of bonding agent added thereto, with satisfactory results. It was found that polyvinyl acetate concentrations above about 130 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 236-241 are identical to Examples 173-179 above, with the exception of the composition of the carrier agent and the amount of bonding agent added thereto, with satisfactory results. It was found that polyvinyl acetate concentrations above about 60 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 173-179.

### EXAMPLES 242-257

| | Bonding Agent | Carrier Agent | |
|---|---|---|---|
| Example | Polyvinyl Acetate | Toluene/Ethyl Alcohol | Application |
| 242 | 130 grams | 875 grams/125 grams | spray |
| 243 | 120 grams | ″ | ″ |
| 244 | 110 grams | ″ | ″ |
| 245 | 100 grams | ″ | ″ |
| 246 | 90 grams | ″ | ″ |
| 247 | 80 grams | ″ | ″ |
| 248 | 70 grams | ″ | ″ |
| 249 | 60 grams | ″ | ″ |
| 250 | 50 grams | ″ | ″ |
| 251 | 70 grams | 875 grams/125 grams | coating |
| 252 | 60 grams | ″ | ″ |
| 253 | 50 grams | ″ | ″ |
| 254 | 40 grams | ″ | ″ |
| 255 | 30 grams | ″ | ″ |
| 256 | 25 grams | ″ | ″ |
| 257 | 20 grams | ″ | ″ |

Examples 242-250 are identical to Examples 165-172 above, with the exception of the composition of the carrier agent, and the amount of bonding agent added thereto, with satisfactory results. It was found that polyvinyl acetate concentrations above about 130 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 251-257 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 173-179.

### EXAMPLES 258-273

| | Bonding Agent | Carrier Agent | |
|---|---|---|---|
| Example | Polyvinyl Acetate | Toluene/Ethyl Alcohol | Application |
| 258 | 150 grams | 850 grams/150 grams | spray |
| 259 | 140 grams | ″ | ″ |
| 260 | 130 grams | ″ | ″ |
| 261 | 120 grams | ″ | ″ |
| 262 | 110 grams | ″ | ″ |
| 263 | 100 grams | ″ | ″ |
| 264 | 90 grams | ″ | ″ |
| 265 | 80 grams | ″ | ″ |
| 266 | 70 grams | ″ | ″ |
| 267 | 60 grams | ″ | ″ |
| 268 | 70 grams | 850 grams/150 grams | coating |
| 269 | 60 grams | ″ | ″ |
| 270 | 50 grams | ″ | ″ |
| 271 | 40 grams | ″ | ″ |
| 272 | 30 grams | ″ | ″ |
| 273 | 25 grams | ″ | ″ |

Examples 258-267 are identical to Examples 165-172 above, with the exception of the composition of the carrier agent, and the amount of bonding agent added thereto, with satisfactory results. It was found that polyvinyl acetate concentrations above about 150 grams resulted in a bonding layer solution which was too thick to be sprayed using the Sada Jet Model J pressurized spray gun, as configured above. It was also found that polyvinyl acetate concentrations below about 60 grams resulted in a bonding layer solution which did not deposit a subjectively sufficient amount of polyvinyl acetate onto the support sheet to make the spray process advantageous, as discussed above with reference to Examples 2-7.

Examples 268-273 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 25 grams resulted in an unusable bonding layer, as discussed above with reference to Examples 173-179.

### EXAMPLES 274-291

| | Bonding Agent | Carrier Agent | |
|---|---|---|---|
| Example | Polyvinyl Acetate | Toluene/Ethyl Alcohol | Application |
| 274 | 140 grams | 825 grams/175 grams | spray |
| 275 | 130 grams | ″ | ″ |
| 276 | 120 grams | ″ | ″ |
| 277 | 110 grams | ″ | ″ |
| 278 | 100 grams | ″ | ″ |
| 279 | 90 grams | ″ | ″ |
| 280 | 80 grams | ″ | ″ |
| 281 | 70 grams | ″ | ″ |
| 282 | 60 grams | ″ | ″ |
| 283 | 50 grams | ″ | ″ |
| 284 | 70 grams | 825 grams/175 grams | coating |
| 285 | 60 grams | ″ | ″ |
| 286 | 50 grams | ″ | ″ |
| 287 | 40 grams | ″ | ″ |
| 288 | 30 grams | ″ | ″ |
| 290 | 25 grams | ″ | ″ |
| 291 | 20 grams | ″ | ″ |

Examples 274-283 are identical to Examples 165-172 above, with the exception of the composition of the carrier agent, and the amount of bonding agent added thereto, with satisfactory results. It was found that polyvinyl acetate concentrations above about 140 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 284-291 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 173-179.

### EXAMPLES 292-306

| | Bonding Agent | Carrier Agent | |
|---|---|---|---|
| Example | Polyvinyl Acetate | Toluene/Ethyl Alcohol | Application |
| 292 | 150 grams | 800 grams/200 grams | spray |
| 293 | 140 grams | ″ | ″ |
| 294 | 130 grams | ″ | ″ |
| 295 | 120 grams | ″ | ″ |
| 296 | 110 grams | ″ | ″ |
| 297 | 100 grams | ″ | ″ |
| 298 | 90 grams | ″ | ″ |
| 299 | 80 grams | ″ | ″ |
| 300 | 70 grams | ″ | ″ |
| 301 | 60 grams | ″ | ″ |
| 302 | 70 grams | 800 grams/200 grams | coating |
| 303 | 60 grams | ″ | ″ |
| 304 | 50 grams | ″ | ″ |
| 305 | 40 grams | ″ | ″ |
| 306 | 30 grams | ″ | ″ |

Examples 292-301 are identical to Examples 165-172 above, with the exception of the composition of the carrier agent, and the amount of bonding agent added thereto, with satisfactory results. It was found that polyvinyl acetate concentrations above about 150 grams resulted in a bonding layer solution which was too thick to be sprayed using the Sada Jet Model J pressurized spray gun, as configured above. It was also found that polyvinyl acetate concentrations below about 60 grams resulted in a bonding layer solution which did not deposit a subjectively sufficient amount of polyvinyl acetate onto the support sheet to make the spray process advantageous, as discussed above with reference to Examples 2-7.

Examples 302-306 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 30 grams resulted in an unusable bonding layer, as discussed above with reference to Examples 173-179.

### EXAMPLES 307-322

| | Bonding Agent | Carrier Agent | |
|---|---|---|---|
| Example | Polyvinyl Acetate | Toluene/Ethyl Alcohol | Application |
| 307 | 150 grams | 775 grams/225 grams | spray |
| 308 | 140 grams | ″ | ″ |
| 309 | 130 grams | ″ | ″ |
| 310 | 120 grams | ″ | ″ |
| 311 | 110 grams | ″ | ″ |
| 312 | 100 grams | ″ | ″ |
| 313 | 90 grams | ″ | ″ |
| 314 | 80 grams | ″ | ″ |
| 315 | 70 grams | ″ | ″ |
| 316 | 60 grams | ″ | ″ |
| 317 | 60 grams | 775 grams/225 grams | coating |
| 318 | 50 grams | ″ | ″ |
| 319 | 40 grams | ″ | ″ |
| 320 | 30 grams | ″ | ″ |
| 321 | 25 grams | ″ | ″ |
| 322 | 20 grams | ″ | ″ |

Examples 307-316 are identical to Examples 165-172 above, with the exception of the composition of the carrier agent, and the amount of bonding agent added thereto, with satisfactory results. It was found that polyvinyl acetate concentrations above about 150 grams resulted in a bonding layer solution which was too thick to be sprayed using the Sada Jet Model J pressurized spray gun, as configured above. It was also found that polyvinyl acetate concentrations below about 60 grams resulted in a bonding layer solution which did not deposit a subjectively sufficient amount of polyvinyl acetate onto the support sheet to make the spray process advantageous, as discussed above with reference to Examples 2-7.

Examples 317-322 are identical to Examples 173-179 above, with the exception of the composition of the carrier agent and the amount of bonding agent added thereto, with satisfactory results. It was found that polyvinyl acetate concentrations above about 60 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 25-33.

### EXAMPLES 323-341

| | Bonding Agent | Carrier Agent | |
|---|---|---|---|
| Example | Polyvinyl Acetate | Toluene/Ethyl Alcohol | Application |
| 323 | 160 grams | 750 grams/250 grams | spray |
| 324 | 150 grams | ″ | ″ |
| 325 | 140 grams | ″ | ″ |
| 326 | 130 grams | ″ | ″ |
| 327 | 120 grams | ″ | ″ |
| 328 | 110 grams | ″ | ″ |
| 329 | 100 grams | ″ | ″ |
| 330 | 90 grams | ″ | ″ |
| 331 | 80 grams | ″ | ″ |
| 332 | 70 grams | ″ | ″ |
| 333 | 60 grams | ″ | ″ |
| 334 | 50 grams | ″ | ″ |
| 335 | 70 grams | 750 grams/250 grams | coating |
| 336 | 60 grams | ″ | ″ |
| 337 | 50 grams | ″ | ″ |
| 338 | 40 grams | ″ | ″ |
| 339 | 30 grams | ″ | ″ |
| 340 | 25 grams | ″ | ″ |
| 341 | 20 grams | ″ | ″ |

Examples 323-334 are identical to Examples 165-172 above, with the exception of the composition of the carrier agent, and the amount of bonding agent added thereto, with satisfactory results. It was found that polyvinyl acetate concentrations above about 160 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 335-341 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 25-33.

### EXAMPLES 342-361

| | Bonding Agent | Carrier Agent | |
|---|---|---|---|
| Example | Polyvinyl Acetate | Toluene/Ethyl Alcohol | Application |
| 342 | 170 grams | 725 grams/275 grams | spray |
| 343 | 160 grams | ″ | ″ |
| 344 | 150 grams | ″ | ″ |
| 345 | 140 grams | ″ | ″ |
| 346 | 130 grams | ″ | ″ |
| 347 | 120 grams | ″ | ″ |
| 348 | 110 grams | ″ | ″ |
| 349 | 100 grams | ″ | ″ |
| 350 | 90 grams | ″ | ″ |
| 351 | 80 grams | ″ | ″ |
| 352 | 70 grams | ″ | ″ |
| 353 | 60 grams | ″ | ″ |
| 354 | 50 grams | ″ | ″ |
| 355 | 70 grams | 725 grams/275 grams | coating |
| 356 | 60 grams | ″ | ″ |
| 357 | 50 grams | ″ | ″ |
| 358 | 40 grams | ″ | ″ |
| 359 | 30 grams | ″ | ″ |
| 360 | 25 grams | ″ | ″ |
| 361 | 20 grams | ″ | ″ |

Examples 342-354 are identical to Examples 165-172 above, with the exception of the composition of the carrier agent, and the amount of bonding agent added thereto, with satisfactory results. It was found that polyvinyl acetate concentrations above about 170 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 355-361 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 25-33.

### EXAMPLES 362-382

| | Bonding Agent | Carrier Agent | |
|---|---|---|---|
| Example | Polyvinyl Acetate | Toluene/Ethyl Alcohol | Application |
| 362 | 180 grams | 700 grams/300 grams | spray |
| 363 | 170 grams | ″ | ″ |
| 364 | 160 grams | ″ | ″ |
| 365 | 150 grams | ″ | ″ |
| 366 | 140 grams | ″ | ″ |
| 367 | 130 grams | ″ | ″ |
| 368 | 120 grams | ″ | ″ |
| 369 | 110 grams | ″ | ″ |
| 370 | 100 grams | ″ | ″ |
| 371 | 90 grams | ″ | ″ |
| 372 | 80 grams | ″ | ″ |
| 373 | 70 grams | ″ | ″ |
| 374 | 60 grams | ″ | ″ |
| 375 | 50 grams | ″ | ″ |
| 376 | 70 grams | 700 grams/300 grams | coating |
| 377 | 60 grams | ″ | ″ |
| 378 | 50 grams | ″ | ″ |
| 389 | 40 grams | ″ | ″ |
| 390 | 30 grams | ″ | ″ |
| 381 | 25 grams | ″ | ″ |
| 382 | 20 grams | ″ | ″ |

Examples 362-375 are identical to Examples 165-172 above, with the exception of the composition of the carrier agent, and the amount of bonding agent added thereto, with satisfactory results. It was found that polyvinyl acetate concentrations above about 180 grams resulted in a bonding layer solution which was too thick to be sprayed using the Sada Jet Model J pressurized spray gun, as configured above. It was also found that polyvinyl acetate concentrations below about 50 grams resulted in a bonding layer solution which did not deposit a subjectively sufficient amount of polyvinyl acetate onto the support sheet to make the spray process advantageous, as discussed above with reference to Examples 2-7.

Examples 376-382 are identical to Examples 173-179 above, with the exception of the composition of the carrier agent and the amount of bonding agent added thereto, with satisfactory results. It was found that polyvinyl acetate concentrations above about 70 grams resulted in a bonding layer which was, in some portions, less fractionable than desired, as discussed above with reference to Examples 8-17. It was also found that polyvinyl acetate concentrations below about 20 grams resulted in an unusable bonding layer, as discussed above with reference to Examples 25-33.

### EXAMPLES 383-385

| | Bonding Agent | Carrier Agent | |
|---|---|---|---|
| Example | Cellulose Acetate | Toluene/Ethyl Alcohol | Application |
| 383 | 100 grams | 700 grams/300 grams | spray |
| 384 | 80 grams | 700 grams/300 grams | spray |
| 385 | 100 grams | 850 grams/150 grams | spray |

Examples 383 and 384 are identical to Example 1 above, with the exception of the composition of the bonding agent (cellulose acetate in lieu of ethylcellulose), the composition of the carrier agent, and the amount of bonding agent added thereto, with satisfactory results.

It was found that cellulose acetate concentrations above about 100 grams, with the carrier agent comprising 85% toluene and 15% ethyl alcohol (Comparative Example 385), resulted in a bonding layer solution which was too thick to be sprayed using the Sada Jet Model J pressurized spray gun, as configured above.

It is to be understood that where in all of the above Examples the bonding layer solution was too thick to be sprayed using the Sada Jet Model J pressurized spray gun as configured above, the use of other spray devices having a more powerful spray capability would be apparent to those skilled in the art having knowledge of the present specification, and such use would extend the upper range on the amount of bonding agent which could be sprayed for each given carrier agent composition.

Additional Embodiments

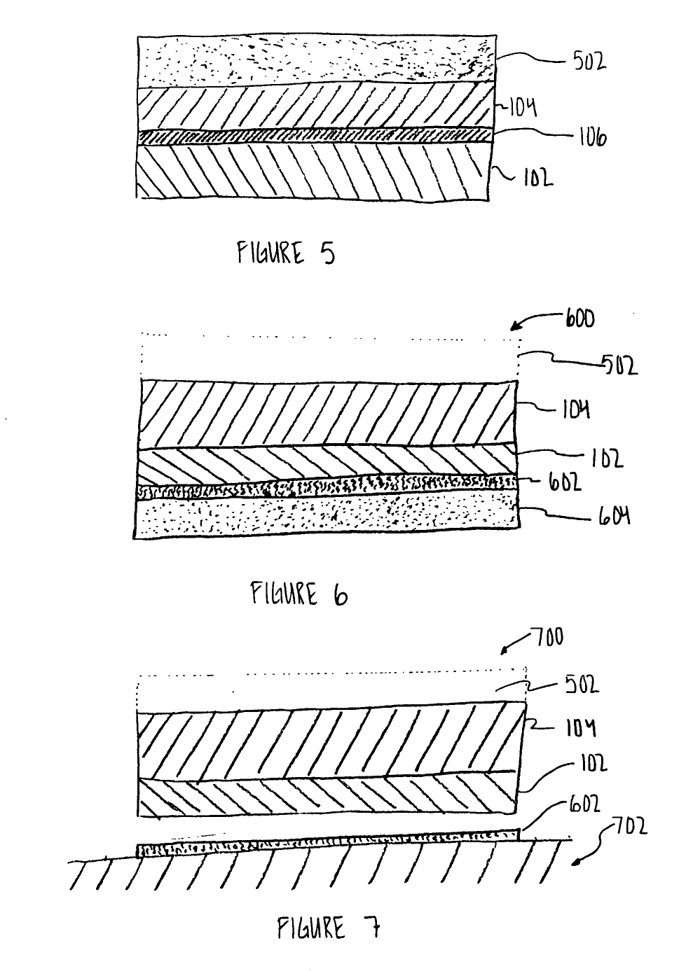

Turning now to FIG. 5, and with reference to FIG. 1 and as discussed above, the user creates the image mask by placing a positive image onto the top surface of the layer of polymer resin composition 104 before exposing the positive image and underlying layer of polymer resin composition to a source of actinic radiation.

Since the layer of polymer resin composition is sensitive to actinic radiation, the user is advised to guard against the accidental exposure of the laminate film thereto from both the support sheet side, as well as the polymer resin composition side.

To diminish the effects of accidental exposure to actinic radiation from the support sheet side, bonding layer 106 and/or support sheet 102 may further comprise an actinic radiation blocker (also referred to as a light absorber).

An example of a suitable actinic radiation blocker for the preferred polymer resin composition is 2,4-dihydroxbenzophenone. The use of other actinic radiation blockers, either in addition to or in lieu of the above, will be apparent to one skilled in the art having knowledge of the present specification.

The amount of actinic radiation blocker added to the bonding layer solution is preferably from about 0.1% to about 0.5% of the bonding agent by weight. Other percentages will be apparent to one skilled in the art having knowledge of the present specification.

In addition to, or in lieu of, any actinic radiation blocker added to the bonding layer solution, an actinic radiation blocker can either be added to the support sheet during the manufacturing process of the support sheet, or can be applied via spray or coating process to one side thereof after the support sheet has been manufactured.

The amount of light blocker to be used in either the support sheet itself during manufacturing or to be applied to one side thereof after the support sheet has been manufactured will be apparent to one skilled in the art having knowledge of the present specification, and will be directly related to the opacity of the support sheet.

In lieu of an actinic radiation blocker, the support sheet can be manufactured with a suitable dye or coloring agent therein to render the support sheet substantially opaque.

Alternatively, the support sheet can be CLEARSIL, manufactured by and available from CPFilms, Inc., of Martinsville, Va., which is a polyester film having a suitable actinic radiation blocker manufactured therein.

To diminish the effects of accidental exposure to actinic radiation from the polymer resin composition side, protective layer 502 (FIG. 5) may be removably-affixed to the layer of polymer resin composition (104) via a low-tack, water-redispersible pressure-sensitive adhesive located therebetween (not shown), or other suitable means as will be apparent to one skilled in the art having knowledge of the present specification.

Protective layer 502 can either be opaque or can comprise an actinic radiation blocker, as discussed above. In the preferred embodiment, protective layer 502 is distinguishable from support sheet 102, either by color, labeling (e.g., “this side up” or “remove to create image mask”) or other indicia, to reduce any confusion by the user as to which layer, 102 or 502, should be removed prior to the creation of the image mask.

Turning now to FIG. 6, a cut-away side view of a further preferred embodiment of the photo-sensitive laminate film of the present invention is illustrated.

Photosensitive laminate film 600 is designed for sandblasting applications where a deeply-etched image is desired, such as the lettering and design applications on tombstones, as well as for sandblasting applications on adamantine substrates, such as marble, granite, metal, concrete and the like, and offers an alternative to computerized laser engraving and the like. Other applications will become apparent to one skilled in the art having knowledge of the present specification.

Photosensitive laminate film 600 preferably comprises polymer resin composition 104 deposited onto one side of support sheet 102, as discussed above. Adhesive layer 602 is applied to the other side of support sheet 102, which is protected by protective layer 604 which is removably-affixed thereto.

Polymer resin composition 104 is preferably water-soluble, such as QTX or QTP as discussed above with reference to FIG. 1, and has a preferred thickness of at least 6 mils, more preferably at least 8 mils. Other thicknesses, dependent upon the specific application, will be apparent to one skilled in the art having knowledge of the present specification.

Support sheet 102 is preferably a non-siliconized, non-coronaized polyester film having an anti-static coating, such as Polyester 770, manufactured by and available from DuPont Corporation, of Wilmington, Del., and the layer of polymer resin composition 104 is preferably applied directly thereto, also as discussed above. Alternatively, support sheet 102 can be any other type of plastic or other material, provided there is good adhesion between polymer resin composition 104 and support sheet 102.

Support sheet 102 is preferably between 2 mils and 5 mils thick, more preferably about 3 mils thick.

Adhesive layer 602 preferably comprises a non-water soluble, relatively aggressive adhesive, such as rubber cement, FREE-FILM manufactured by TeckniCoat of Miamisburg, Ohio., or XS-385 manufactured by Dyna-Tech of Carlton, W.Va. Other adhesives, both water-soluble and non-water soluble, will be apparent to one skilled in the art having knowledge of the present specification.

Adhesive layer 602 is preferably between 0.5 mils and 1 mil thick.

Protective layer 604 is preferably a siliconized polyester sheet to facilitate the removal thereof, preferably about 3 mils thick.

To diminish the effects of accidental exposure to actinic radiation from the polymer resin composition side, protective layer 502 may optionally be removably-affixed to polymer resin composition 104 via a low-tack, water-redispersible pressure-sensitive adhesive located therebetween (not shown).

Protective layer 502 can either be opaque or can comprise a light absorber, and can be distinguishable from protective layer 604, either by color, labeling or other indicia to reduce any confusion by the user as to which layer, 502 or 604, should be removed to create an image mask, each as discussed above.

In use, an image mask is created from polymer resin composition 104 , as discussed above. Thereafter, protective layer 604 is capable of being removed to allow the image mask affixed to support sheet 102 to be affixed to the substrate via adhesive layer 602. During the sandblasting process, the sand first removes the areas of support sheet 102 and adhesive layer 602 which are not protected by the image mask, and then blasts the substrate until the user is satisfied with the depth of etching. The remaining portions of the image mask, support sheet and adhesive layer can then be removed from the substrate by any conventional process, such as rolled off, scraped off with a razor blade, or removed via applicable solvent to dissolve the adhesive layer.

While photosensitive laminate film 600 represents a self-contained unit for the user, there may be situations where the user desires to control the application of the adhesive on the substrate.

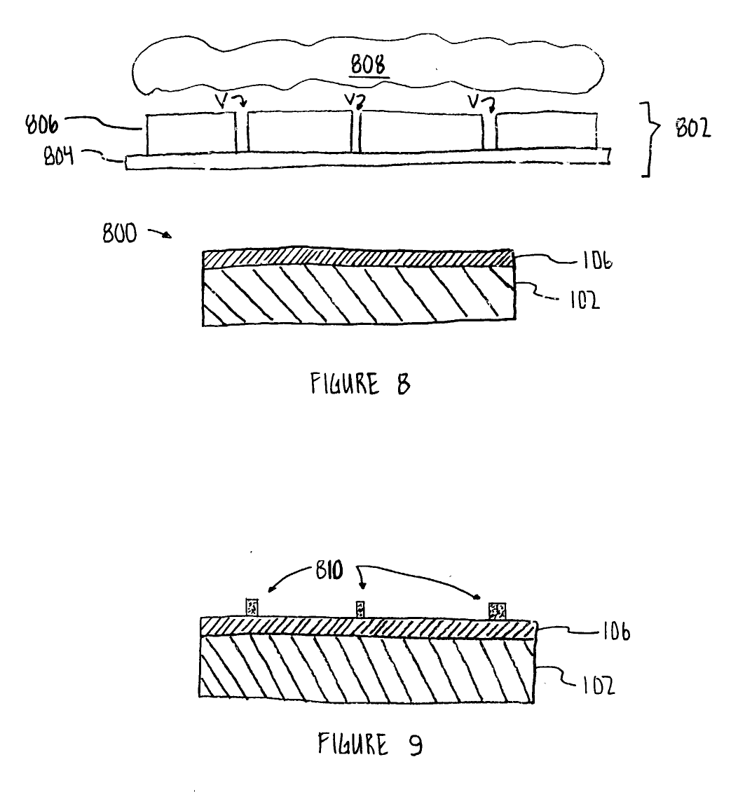

Accordingly, and with reference to FIG. 7, photosensitive laminate film 700 preferably comprises polymer resin composition 104 deposited onto one side of support sheet 102, as discussed above with reference to FIG. 6.

Protective layer 502 may optionally be removably-affixed to polymer resin composition 104, as discussed above with reference to FIG. 6.

In use, after the image mask has been created by the user, the user can apply a layer of adhesive 602 to the surface of substrate 702 (or to the bottom surface of support sheet 102) prior to the application of the support sheet/image mask on the substrate. The substrate can then be sandblasted, and the remaining portions of the image mask and support sheet can thereafter be removed from the substrate, as discussed above with reference to FIG. 6.

Turning now to FIG. 8, a cut-away side view of a further preferred embodiment of the photo-sensitive laminate film of the present invention is illustrated.

Laminate film 800, preferably comprising support sheet 102 and fractionally-releasable bonding layer 106 as discussed above, is designed to allow an image mask or image to be applied directly onto the surface of bonding layer 106.

Stencil 802 preferably comprises image mask 806 adhered in conventional manner to silkscreen support sheet 804. Image mask 806 typically comprises a plurality of voids V, defining an image to be transferred to the top surface of bonding layer 106. As appreciated by those skilled in the art, silkscreen support sheet 804 is porous, allowing fluid 808 to pass therethrough via voids V.

In use, stencil 802 is placed over laminate film 800 such that silkscreen support sheet 804 is in contact with the top surface of bonding layer 106.

In applications where stencil 802 is used to create an image mask to be applied to a substrate for etching, fluid 808 is preferably a rubberized ink, such as an silkscreenable, acrylic printing ink available from SpeedBall Art Products Company of Statesville, N.C. Other fluids, such as a polymer-based ink, will be apparent to one skilled in the art having knowledge of the present specification.

After the rubberized ink is applied in conventional manner over the surface of image mask 806, that portion of the rubberized ink which passed through voids V and silkscreen support sheet 804 is deposited onto the top surface of bonding layer 106 as image mask 810, as shown with reference to FIG. 9.

The rubberized ink which has been deposited onto the top surface of bonding layer 106 as image mask 810 can be transferred to a substrate by preferably applying a layer of high-tack, water-redispersible pressure-sensitive adhesive onto a desired surface of the substrate, placing the image mask into the layer of adhesive, applying slight pressure to support sheet 102, and removing support sheet 102 therefrom, thereby resulting in image mask 810 being adhered to the surface of the substrate.

As discussed above, that portion of bonding layer 106 which is not adhered to image mask 810 will preferably be removed with support sheet 102 (provided it has not otherwise adhered itself to the layer of adhesive located on the surface of the substrate).

The rubberized ink, when applied as above to create image mask 810, is resilient to both a chemical etching solution, as well as light sandblasting treatment. In the preferred embodiment, however, image mask 810 is preferably used with a chemical etching solution, such as ARMOUR ETCH, an acid-based etching creme available from Armour Products of Wykoff, N.J.

After the surface of the substrate has been etched, image mask 810 is removable from the substrate via water (if the adhesive was a water-redispersible adhesive) or solvent (if the adhesive was a solvent-redispersible adhesive).

In applications where stencil 802 is used to create an image to be applied to the surface of a substrate as artwork or other ornamental feature or design, fluid 808 is preferably a colored medium, such as paint. In such applications, a plurality of stencils 802 can be used, each stencil comprising voids V which represent the pattern of a single color to be applied.

In use, the stencils can preferably be placed one at a time over laminate film 800 such that silkscreen support sheet 804 is in contact with the top surface of bonding layer 106, and the particular paint color passes through the stencil onto the top surface of bonding layer 106.

After the plurality of paint colors have been applied via the plurality of stencils, the artwork residing on the top surface of bonding layer 106 can be applied to a substrate in any number of ways.

For example, the artwork can be applied to one side of a glass panel via pressure or a thin layer of adhesive, with the viewing surface of the artwork being either side of the glass panel. Alternatively, the artwork can be applied to a substrate via pressure or a thin layer of adhesive, with the viewing surface being the other side of the artwork (i.e., the side of the artwork in contact with bonding layer 106), in which case the bonding layer which transferred to the artwork after support sheet 102 had been removed can optionally be removed from the artwork via dabbing same with a solvent to dissolve the bonding layer therefrom.

An advantage of the embodiment shown with reference to FIGS. 8 and 9 is that a plurality of identical image masks and/or artwork images can be manufactured quickly, efficiently and economically, as compared to either the methods discussed hereinabove with reference to FIGS. 1 through 3 and/or conventional prior art methods.

By way of example, the embodiment shown with reference to FIGS. 8 and 9 is advantageous where a uniform image mask needs to be created to etch the identical image onto a plurality of substrates, such as lettering or corporate logos on coffee mugs, pin stripping or other artwork on automobiles, cars and motorcycles, or image masks designed for mass sale and/or distribution. Additionally, the embodiment shown with reference to FIGS. 8 and 9 is advantageous where a plurality of identical artwork images need to be created in one location to be applied in the field at various other locations. Other applications will be apparent to one skilled in the art having knowledge of the present specification.

As an alternative to creating an artwork image using stencil(s) 802, a user may apply his or her artwork directly onto the surface of bonding layer 106 in a freestyle manner, for example, using paint or paint sticks. Other media will be apparent to one skilled in the art having knowledge of the present specification.

While the present invention has been described above with reference to particular applications, it is to be understood that the present invention is not so limited. The present invention can also be used in other applications.

For example, the present invention can be used in the manufacture of printed circuit boards. Starting with a “blank” circuit board having a solid copper film affixed to at least one side of the board, an image mask can be created having a pattern identical to the desired copper line pattern which is to remain on the board. The image mask is adhered to the copper film, and the board is placed in an acid bath which removes the exposed copper (i.e., that portion of the copper film not protected by the image mask). Thereafter, the image mask is removed, revealing a circuit board having the desired copper line pattern.

The present invention can also be used in glue chipping applications, where an image mask can be created, applied to the surface of a glass sheet and used as a stencil or outline for the application of glue.

Glue chipping is a technique whereby an animal/based glue is applied to a predetermined portion of a glass sheet, which predetermined portion typically had previously been roughened (e.g., by sand paper, sandblasting or the application of a chemical etching solution). As the glue dries, it contracts, thereby pulling (or chipping) micro-sized pieces of glass from the surface, resulting in a particular surface effect on the glass. The size of the micro-chips is typically dependent upon the viscosity of the glue, the amount of glue used, the ambient temperature and humidity (which affects dying time), and the like.

Similarly, the present invention can be used in painting or gold leaf applications, where an image mask can be created, applied to the surface of a substrate and used as a stencil or outline for applying paint or gold leaf to the surface of the substrate. For example, an automobile, motorcycle, boat or other vehicle can be pin-stripped or have any other design or logo painted thereon, either on an unpainted, an otherwise painted or chrome portion thereof.

A user may optionally choose to slightly etch such surface prior to the application of paint in order to provide a relatively rougher surface onto which the paint can adhere. Such slight etching has been found to be preferable in chrome-painting applications.

Although illustrative embodiments of the present invention have been described in detail with reference to the accompanying drawings, it is to be understood that the invention is not limited to those precise embodiments. Various changes or modifications may be effected therein by one skilled in the art without departing from the scope or spirit of the invention.

What we claim as our invention is:

1. A photo-sensitive laminate film for use in making an image mask, the photo-sensitive laminate film comprising:
a support sheet having a first surface and a second surface;
a layer of polymer resin composition having photocrosslinkability, the layer of polymer resin composition having a first surface and a second surface; and
a fractionally-releasable bonding layer operatively located between the first surface of the support sheet and the second surface of the layer of polymer resin composition;
wherein, upon the creation of an image mask from the layer of polymer resin composition, the support sheet is capable of being separated from the image mask.

2. The photo-sensitive laminate film of claim 1, wherein the support sheet is a siliconized polyester film.

3. The photo-sensitive laminate film of claim 1, wherein the support sheet is a non-siliconized polyester film.

4. The photo-sensitive laminate film of claim 1, wherein the support sheet comprises an actinic radiation blocker.

5. The photo-sensitive laminate film of claim 1, wherein the support sheet is substantially opaque.

6. The photo-sensitive laminate film of claim 1, wherein the fractionally-releasable bonding layer comprises an actinic radiation blocker.

7. The photo-sensitive laminate film of claim 1, wherein the fractionally-releasable bonding layer comprises an antioxidant.

8. The photo-sensitive laminate film of claim 1, wherein the fractionally-releasable bonding layer comprises ethylcellulose.

9. The photo-sensitive laminate film of claim 1, wherein the fractionally-releasable bonding layer comprises polyvinyl acetate.

10. The photo-sensitive laminate film of claim 1, wherein the fractionally-releasable bonding layer comprises cellulose acetate.

11. The photo-sensitive laminate film of claim 1, wherein the fractionally-releasable bonding layer comprises a member selected from the group consisting of ethylcellulose, polyvinyl acetate, cellulose acetate, cellulose nitrate, polyvinyl acetate chemically reacted with pyrrolidone copolymer, polyvinyl pyrrolidone and polyvinyl alcohol.

12. The photo-sensitive laminate film of claim 11, wherein the fractionally-releasable bonding layer further comprises an actinic radiation blocker.

13. The photo-sensitive laminate film of claim 11, wherein the fractionally-releasable bonding layer further comprises an antioxidant.

14. The photo-sensitive laminate film of claim 1, wherein the fractionally-releasable bonding layer is a discontinuous micro-dot pattern.

15. The photo-sensitive laminate film of claim 1, wherein the fractionally-releasable bonding layer is a substantially continuous pattern.

16. The photo-sensitive laminate film of claim 1 further comprising a protective layer having a first surface and a second surface, wherein the second surface of the protective layer is removably-attached to the first surface of the layer of polymer resin composition, and wherein the protective layer is removable therefrom prior to the creation of the image mask.

17. The photo-sensitive laminate film of claim 16, wherein the protective layer is opaque.

18. The photo-sensitive laminate film of claim 16, wherein the protective layer comprises an actinic radiation blocker.

19. The photo-sensitive laminate film of claim 16, wherein the protective layer is distinguishable from the support sheet to clarify that it is the protective layer and not the support sheet which is removable prior to the creation of the image mask.

20. The photo-sensitive laminate film of claim 1, wherein, upon the creation of the image mask from the layer of polymer resin composition, the image mask is capable of being separated from the first surface of the support sheet such that at least a portion of the bonding layer located between the image mask and the first surface of the support sheet is released from the support sheet with the image mask, and the remaining portion of the bonding layer remains with the support sheet.

21. The photo-sensitive laminate film of claim 1, wherein, upon the creation of the image mask from the layer of polymer resin composition, the image mask having at least one portion of crosslinked polymer resin composition and at least one portion devoid of any crosslinked polymer resin composition, the support sheet is capable of being separated from the image mask such that substantially all of the bonding layer which is not located between the image mask and the first surface of the support sheet remains with the support sheet.

22. The photo-sensitive laminate film of claim 1, wherein, upon the creation of the image mask from the layer of polymer resin composition, the image mask is capable of being separated from the first surface of the support sheet such that a first portion of the bonding layer is released from the support sheet with the image mask, and a second portion of the bonding layer remains with the support sheet.

23. The photo-sensitive laminate film of claim 1, wherein, upon the creation of the image mask from the layer of polymer resin composition, the support sheet is capable of being separated from the image mask such that at least a portion of the bonding layer located on the first surface of the support sheet remains with the support sheet after the image mask has been separated therefrom.

24. The photo-sensitive laminate film of claim 1, wherein, upon the creation of the image mask from the layer of polymer resin composition, the support sheet is capable of being separated from the image mask such that a portion of the bonding layer located on the first surface of the support sheet remains with the support sheet after the image mask has been separated therefrom.

25. The photo-sensitive laminate film of claim 1, wherein, upon the creation of the image mask from the layer of polymer resin composition, the support sheet is capable of being separated from the image mask such that substantially only a portion of the bonding layer which is located on the first surface of the support sheet is released with the image mask when the image mask is separated from the support sheet.

26. The photo-sensitive laminate film of claim 1, wherein, upon the creation of the image mask from the layer of polymer resin composition, the support sheet is capable of being separated from the image mask such that substantially only that portion of the bonding layer which is located between the image mask and the first surface of the support sheet is released with the image mask when the image mask is separated from the support sheet.

27. A laminate film comprising:
a support sheet having a first surface and a second surface; and
a fractionally-releasable bonding layer having a first surface and a second surface, the second surface of the bonding layer operatively located on the first surface of the support sheet;
wherein an image mask having a first surface and a second surface is capable of being operatively located on the bonding layer such that the second surface of the image mask is located on at least a portion of the first surface of the bonding layer, and wherein the support sheet is capable of being separated from the image mask.

28. The laminate film of claim 27, wherein the image mask is created from a layer of polymer resin composition having photocrosslinkability, the layer of polymer resin composition having a first surface and a second surface, the first and second surfaces thereof corresponding to the first and second surfaces, respectively, of the image mask.

29. The laminate film of claim 27, wherein the image mask comprises rubberized ink.

30. The laminate film of claim 27, wherein the support sheet is a siliconized polyester film.

31. The laminate film of claim 27, wherein the support sheet is a non-siliconized polyester film.

32. The laminate film of claim 27, wherein the support sheet comprises an actinic radiation blocker.

33. The laminate film of claim 27, wherein the support sheet is substantially opaque.

34. The laminate film of claim 27, wherein the fractionally-releasable bonding layer comprises an actinic radiation blocker.

35. The laminate film of claim 27, wherein the fractionally-releasable bonding layer comprises an antioxidant.

36. The laminate film of claim 27, wherein the fractionally-releasable bonding layer comprises ethylcellulose.

37. The laminate film of claim 27, wherein the fractionally-releasable bonding layer comprises polyvinyl acetate.

38. The laminate film of claim 27, wherein the fractionally-releasable bonding layer comprises cellulose acetate.

39. The laminate film of claim 27, wherein the fractionally-releasable bonding layer comprises a member selected from the group consisting of ethylcellulose, polyvinyl acetate, cellulose acetate, cellulose nitrate, and polyvinyl acetate chemically reacted with pyrrolidone copolymer, polyvinyl pyrrolidone and polyvinyl alcohol.

40. The laminate film of claim 39, wherein the fractionally-releasable bonding layer further comprises an actinic radiation blocker.

41. The laminate film of claim 39, wherein the fractionally-releasable bonding layer further comprises an antioxidant.

42. The laminate film of claim 27, wherein the fractionally-releasable bonding layer is a discontinuous micro-dot pattern.

43. The laminate film of claim 27, wherein the fractionally-releasable bonding layer is a substantially continuous pattern.

44. The laminate film of claim 27, wherein, the image mask is capable of being separated from the first surface of the support sheet such that at least a portion of the bonding layer located between the second surface of the image mask and the first surface of the support sheet is released from the support sheet with the image mask, and the remaining portion of the bonding layer located on the support sheet remains with the support sheet.

45. The laminate film of claim 27, wherein, the support sheet is capable of being separated from the image mask such that substantially all of the bonding layer which is not located between the second surface of the image mask and the first surface of the support sheet remains with the support sheet.

46. The laminate film of claim 27, wherein, the image mask is capable of being separated from the first surface of the support sheet such that a first portion of the bonding layer is released from the support sheet with the image mask, and a second portion of the bonding layer remains with the support sheet.

47. The laminate film of claim 27, wherein, the support sheet is capable of being separated from the image mask such that at least a portion of the bonding layer located on the first surface of the support sheet remains with the support sheet after the image mask has been separated therefrom.

48. The laminate film of claim 27, wherein, the support sheet is capable of being separated from the image mask such that a portion of the bonding layer located on the first surface of the support sheet remains with the support sheet after the image mask has been separated therefrom.

49. The laminate film of claim 27, wherein, the support sheet is capable of being separated from the image mask such that substantially only a portion of the bonding layer is released with the image mask when the image mask is separated from the support sheet.

50. The laminate film of claim 27, wherein, the support sheet is capable of being separated from the image mask such that substantially only that portion of the bonding layer which is located between the second surface of the image mask and the first surface of the support sheet is released with the image mask when the image mask is separated from the support sheet.

51. A laminate film comprising:
a support sheet having a first surface and a second surface; and
a fractionally-releasable bonding layer having a first surface and a second surface, the second surface of the bonding layer operatively located on the first surface of the support sheet;
wherein an image is capable of being applied to at least a portion of the first surface of the bonding layer, and wherein the support sheet is capable of being separated from the image.

52. The laminate film of claim 51, wherein the image comprises a colored medium.

53. The laminate film of claim 52, wherein the colored medium comprises a member selected from the group consisting of paint and paint sticks.

54. The laminate film of claim 51, wherein the support sheet is a siliconized polyester film.

55. The laminate film of claim 51, wherein the support sheet is a non-siliconized polyester film.

56. The laminate film of claim 51, wherein the support sheet comprises an actinic radiation blocker.

57. The laminate film of claim 51, wherein the support sheet is substantially opaque.

58. The laminate film of claim 51, wherein the fractionally-releasable bonding layer comprises an actinic radiation blocker.

59. The laminate film of claim 51, wherein the fractionally-releasable bonding layer comprises an antioxidant.

60. The laminate film of claim 51, wherein the fractionally-releasable bonding layer comprises ethylcellulose.

61. The laminate film of claim 51, wherein the fractionally-releasable bonding layer comprises polyvinyl acetate.

62. The laminate film of claim 51, wherein the fractionally-releasable bonding layer comprises cellulose acetate.

63. The laminate film of claim 51, wherein the fractionally-releasable bonding layer comprises a member selected from the group consisting of ethylcellulose, polyvinyl acetate, cellulose acetate, cellulose nitrate, and polyvinyl acetate chemically reacted with pyrrolidone copolymer, polyvinyl pyrrolidone and polyvinyl alcohol.

64. The laminate film of claim 63, wherein the fractionally-releasable bonding layer further comprises an actinic radiation blocker.

65. The laminate film of claim 63, wherein the fractionally-releasable bonding layer further comprises an antioxidant.

66. The laminate film of claim 51, wherein the fractionally-releasable bonding layer is a discontinuous micro-dot pattern.

67. The laminate film of claim 51, wherein the fractionally-releasable bonding layer is a substantially continuous pattern.

68. A product comprising:
an image mask defined by a predetermined pattern having a first surface and second surface, wherein the first surface of the image mask is capable of being operatively attached to a substrate; and
a bonding layer operatively attached to the second surface of the image mask, wherein the bonding layer has a pattern substantially corresponding to and substantially coincident with the predetermined pattern of the image mask.

69. The product of claim 68, wherein the image mask comprises a crosslinked polymer resin composition.

70. The product of claim 68, wherein the image mask comprises rubberized ink.

71. The product of claim 68, wherein, upon operatively attaching the first surface of the image mask to the substrate, the substrate is capable of being etched with an image corresponding inversely to the predetermined pattern of the image mask.

72. A product comprising:
an image mask defined by a predetermined pattern having a first surface and second surface, wherein the first surface of the image mask is capable of being operatively attached to a substrate; and
a bonding layer operatively attached to the second surface of the image mask, wherein the bonding layer has a pattern substantially commeasurable to and coextensive with the predetermined pattern of the image mask.

73. The product of claim 72, wherein the image mask comprises a crosslinked polymer resin composition.

74. The product of claim 72, wherein the image mask comprises rubberized ink.

75. The product of claim 72, wherein, upon operatively attaching the first surface of the image mask to the substrate, the substrate is capable of being etched with an image corresponding inversely to the predetermined pattern of the image mask.

76. A product for etching an image on a substrate, the product comprising:
an image mask defined by a predetermined pattern having a first surface and second surface, wherein the first surface of the image mask is operatively attached to the substrate; and
a bonding layer operatively attached to the second surface of the image mask, wherein the bonding layer has a pattern substantially corresponding to and substantially coincident with the predetermined pattern of the image mask;
wherein, the substrate is capable of being etched with an image corresponding inversely to the predetermined pattern of the image mask.

77. The product of claim 76, wherein the image mask comprises a crosslinked polymer resin composition.

78. The product of claim 76, wherein the image mask comprises rubberized ink.

79. A product for etching an image on a substrate, the product comprising:
an image mask defined by a predetermined pattern having a first surface and second surface, wherein the first surface of the image mask is operatively attached to the substrate; and
a bonding layer operatively attached to the second surface of the image mask, wherein the bonding layer has a pattern substantially commeasurable to and coextensive with the predetermined pattern of the image mask;
wherein, the substrate is capable of being etched with an image corresponding inversely to the predetermined pattern of the image mask.

80. The product of claim 79, wherein the image mask comprises a crosslinked polymer resin composition.

81. The product of claim 79, wherein the image mask comprises rubberized ink.

82. A photo-sensitive laminate film comprising:
a layer of polymer resin composition having photocrosslinkability, the layer of polymer resin composition having a first surface and a second surface;
a support sheet having a first surface, attached to the second surface of the layer of polymer resin composition, and a second surface;
adhesive operatively affixed to the second surface of the support sheet; and
an adhesive protection layer removably adhered to the adhesive.

83. The photo-sensitive laminate film of claim 82, wherein, upon the creation of an image mask from the layer of polymer resin composition, the support sheet is capable of being operatively attached to a substrate by removing the adhesive protection layer and allowing the adhesive located on the second surface of the support sheet to contact the substrate.

84. The photo-sensitive laminate film of claim 82, wherein the support sheet is a non-siliconized polyester film.

85. The photo-sensitive laminate film of claim 82, wherein the support sheet comprises an actinic radiation blocker.

86. The photo-sensitive laminate film of claim 82, wherein the support sheet is substantially opaque.

87. The photo-sensitive laminate film of claim 82 further comprising a protective layer removably-attached to the first surface of the layer of polymer resin composition, wherein the protective layer is removable therefrom prior to the creation of an image mask from the layer of polymer resin composition.

88. The photo-sensitive laminate film of claim 87, wherein the protective layer is opaque.

89. The photo-sensitive laminate film of claim 87, wherein the protective layer comprises an actinic radiation blocker.

90. The photo-sensitive laminate film of claim 87 wherein the protective layer is distinguishable from the adhesive protection layer to clarify that it is the protective layer and not the adhesive protection layer which is removable prior to the creation of the image mask.

91. A photo-sensitive laminate film for use in making an image mask for use with etching an image onto a substrate, the photo-sensitive laminate film comprising:
a layer of polymer resin composition having photocrosslinkability, the layer of polymer resin composition having a first surface and a second surface; and
a support sheet having a first surface, attached to and in contact with the second surface of the layer of polymer resin composition, and a second surface;
wherein, upon the creation of an image mask from the layer of polymer resin composition, the image mask is capable of being used to etched an image onto a substrate.

92. The photo-sensitive laminate film of claim 91 further comprising:
a layer of adhesive operatively affixed to the second surface of the support sheet; and
an adhesive protection layer removably adhered to the layer of adhesive.

93. The photo-sensitive laminate film of claim 92, wherein, upon the creation of an image mask from the layer of polymer resin composition, the support sheet is capable of being operatively attached to a substrate by removing the adhesive protection layer and allowing the layer of adhesive located on the second surface of the support sheet to contact the substrate, and wherein, the substrate is capable of being etched with an image corresponding inversely to the image mask.

94. The photo-sensitive laminate film of claim 91, wherein, upon the creation of an image mask from the layer of polymer resin composition, the second surface of the support sheet is capable of being operatively attached to the substrate, and wherein, the substrate is capable of being etched with an image corresponding inversely to the image mask.

95. The photo-sensitive laminate film of claim 91, wherein the support sheet is a non-siliconized polyester film.

96. The photo-sensitive laminate film of claim 91, wherein the support sheet comprises an actinic radiation blocker.

97. The photo-sensitive laminate film of claim 91, wherein the support sheet is substantially opaque.

98. The photo-sensitive laminate film of claim 91 further comprising a protective layer removably-attached to the first surface of the layer of polymer resin composition, wherein the protective layer is removable therefrom prior to the creation of the image mask from the layer of polymer resin composition.

99. The photo-sensitive laminate film of claim 98, wherein the protective layer is opaque.

100. The photo-sensitive laminate film of claim 98, wherein the protective layer comprises an actinic radiation blocker.

101. The photo-sensitive laminate film of claim 98 wherein the protective layer is distinguishable from the support sheet to clarify that it is the protective layer and not the support sheet which is removable prior to the creation of the image mask.

102. A product comprising:
an image mask defined by a predetermined pattern having a first surface and second surface; and
a support sheet having a first surface, attached to and in contact with the second surface of the image mask, and a second surface.

103. The product of claim 102 further comprising:
adhesive operatively affixed to the second surface of the support sheet; and
an adhesive protection layer removably adhered to the adhesive.

104. The product of claim 103, wherein, the support sheet is capable of being operatively attached to a substrate by removing the adhesive protection layer and allowing the adhesive located on the second surface of the support sheet to contact the substrate, and wherein, the substrate is capable of being etched with an image corresponding inversely to the image mask.

105. The product of claim 102, wherein, the second surface of the support sheet is capable of being operatively attached to a substrate, and wherein, the substrate is capable of being etched with an image corresponding inversely to the image mask.

106. The product of claim 102, wherein, the second surface of the support sheet is operatively attached to a substrate, and wherein, the substrate is capable of being etched with an image corresponding inversely to the image mask.

107. The product of claim 102, wherein, the first surface of the image mask is capable of being operatively attached to a substrate, and wherein, the substrate is capable of being etched with an image corresponding inversely to the image mask.

108. The product of claim 102, wherein, the first surface of the image mask is operatively attached to a substrate, and wherein, the substrate is capable of being etched with an image corresponding inversely to the image mask.

109. The product of claim 102, wherein the support sheet is a non-siliconized polyester film.

110. The product of claim 102, wherein the support sheet comprises an actinic radiation blocker.

111. The product of claim 102, wherein the support sheet is substantially opaque.

112. A photo-sensitive laminate film for use in making an image mask, the photo-sensitive laminate film comprising:
a support sheet having a first surface and a second surface, the support sheet comprising an actinic radiation blocker;
a layer of polymer resin composition having photocrosslinkability, the layer of polymer resin composition having a first surface and a second surface; and
a bonding layer operatively located between the first surface of the support sheet and the second surface of the layer of polymer resin composition;
wherein, upon the creation of an image mask from the layer of polymer resin composition, the support sheet is capable of being separated from the image mask.

113. The photo-sensitive laminate film of claim 112, wherein the bonding layer is fractionally-releasable.

114. A photo-sensitive laminate film for use in making an image mask, the photo-sensitive laminate film comprising:
a substantially opaque support sheet having a first surface and a second surface;
a layer of polymer resin composition having photocrosslinkability, the layer of polymer resin composition having a first surface and a second surface; and
a bonding layer operatively located between the first surface of the support sheet and the second surface of the layer of polymer resin composition;
wherein, upon the creation of an image mask from the layer of polymer resin composition, the support sheet is capable of being separated from the image mask.

115. The photo-sensitive laminate film of claim 114, wherein the bonding layer is fractionally-releasable.

116. A photo-sensitive laminate film for use in making an image mask, the photo-sensitive laminate film comprising:
a support sheet having a first surface and a second surface;
a layer of polymer resin composition having photocrosslinkability, the layer of polymer resin composition having a first surface and a second surface; and
a bonding layer operatively located between the first surface of the support sheet and the second surface of the layer of polymer resin composition, the bonding layer comprising an antioxidant;
wherein, upon the creation of an image mask from the layer of polymer resin composition, the support sheet is capable of being separated from the image mask.

117. The photo-sensitive laminate film of claim 116, wherein the bonding layer is fractionally-releasable.

118. A photo-sensitive laminate film for use in making an image mask, the photo-sensitive laminate film comprising:
a support sheet having a first surface and a second surface;
a layer of polymer resin composition having photocrosslinkability, the layer of polymer resin composition having a first surface and a second surface; and
a bonding layer operatively located between the first surface of the support sheet and the second surface of the layer of polymer resin composition, the bonding layer comprising an actinic radiation blocker;
wherein, upon the creation of an image mask from the layer of polymer resin composition, the support sheet is capable of being separated from the image mask.

119. The photo-sensitive laminate film of claim 118, wherein the bonding layer is fractionally-releasable.

120. A method of making a photo-sensitive laminate film, said method comprising the steps of:
forming a fractionally-releasable bonding layer onto a first surface of a support sheet; and
applying a layer of polymer resin composition having photocrosslinkability to the fractionally-releasable bonding layer.

121. The method of claim 120, said method further comprising the step of creating an image mask from the layer of polymer resin composition, the image mask being operatively attached to the first surface of the support sheet via the fractionally-releasable bonding layer.

122. The method of claim 121, said method further comprising the step of separating the image mask from the first surface of a support sheet such that at least a portion of the bonding layer located between the image mask and the first surface of the support sheet is released from the support sheet with the image mask, and the remaining portion of the bonding layer remains with the support sheet.

123. The method of claim 121, said method further comprising the step of separating the image mask from the first surface of a support sheet such that a first portion of the bonding layer is released from the support sheet with the image mask, and a second portion of the bonding layer remains with the support sheet.

124. The method of claim 121, said method further comprising the step of separating the image mask from the first surface of a support sheet such that a portion of the bonding layer located on the first surface of the support sheet remains with the support sheet after the image mask has been separated therefrom.

125. The method of claim 121, said method further comprising the step of separating the image mask from the first surface of a support sheet such that substantially only a portion of the bonding layer which is located on the first surface of the support sheet is released with the image mask when the image mask is separated from the support sheet.

126. The method of claim 121, said method further comprising the step of separating the image mask from the first surface of a support sheet such that substantially only that portion of the bonding layer which is located between the image mask and the first surface of the support sheet is released with the image mask when the image mask is separated from the support sheet.

127. The method of claim 120, said method further comprising the step of creating an image mask from the layer of polymer resin composition, the image mask being operatively attached to the first surface of the support sheet via the fractionally-releasable bonding layer, the image mask having at least one portion of crosslinked polymer resin composition and at least one portion devoid of any crosslinked polymer resin composition,

128. The method of claim 127, said method further comprising the step of separating the image mask from the first surface of a support sheet such that substantially all of the bonding layer which is not located between the image mask and the first surface of the support sheet remains with the support sheet.

129. The method of claim 120, said method further comprising the steps of:
creating an image mask from the layer of polymer resin composition, the image mask being defined by a predetermined pattern having a first surface and second surface, the second surface of the image mask being operatively attached to the first surface of the support sheet via the fractionally-releasable bonding layer;
operatively attaching the first surface of the image mask to a substrate; and
removing the support sheet.

130. The method of claim 129, said method further comprising the step of etching the substrate with an image corresponding inversely to the predetermined pattern of the image mask.

131. The method of claim 120, wherein the step of forming the fractionally-releasable bonding layer onto a first surface of a support sheet comprises the steps of:
combining a bonding agent and a carrier agent to form a bonding layer solution;
applying the bonding layer solution to the first surface of a support sheet; and
allowing the bonding layer solution to evaporate, thereby resulting in the formation of the fractionally-releasable bonding layer on the first surface of a support sheet.

132. The method of claim 131, wherein the step of applying the bonding layer solution to the first surface of a support sheet comprises the step of spraying the bonding layer solution onto the first surface of a support sheet.

133. The method of claim 132, wherein the bonding agent comprises ethylcellulose.

134. The method of claim 133, wherein the amount of the bonding agent is between about 2% and about 17% of the carrier agent by weight.

135. The method of claim 133, wherein the carrier agent comprises toluene and a viscosity reducer.

136. The method of claim 135, wherein the viscosity reducer comprises ethyl alcohol.

137. The method of claim 135, wherein the ratio of toluene to the viscosity reducer is between about 60:40 to about 100:0 of the carrier agent by weight.

138. The method of claim 132, wherein the bonding agent comprises polyvinyl acetate.

139. The method of claim 138, wherein the amount of the bonding agent is between about 5% and about 18% of the carrier agent by weight.

140. The method of claim 138, wherein the carrier agent comprises toluene and a viscosity reducer.

141. The method of claim 140, wherein the viscosity reducer comprises ethyl alcohol.

142. The method of claim 140, wherein the ratio of toluene to the viscosity reducer is between about 70:30 to about 99:1 of the carrier agent by weight.

143. The method of claim 131, wherein the step of applying the bonding layer solution to the first surface of a support sheet comprises the step of coating the first surface of a support sheet with the bonding layer solution.

144. The method of claim 143, wherein the bonding agent comprises ethylcellulose.

145. The method of claim 144, wherein the amount of the bonding agent is between about 0.5% and about 2% of the carrier agent by weight.

146. The method of claim 144, wherein the carrier agent comprises toluene and a viscosity reducer.

147. The method of claim 146, wherein the viscosity reducer comprises ethyl alcohol.

148. The method of claim 146, wherein the ratio of toluene to the viscosity reducer is between about 60:40 to about 100:0 of the carrier agent by weight.

149. The method of claim 143, wherein the bonding agent comprises polyvinyl acetate.

150. The method of claim 149, wherein the amount of the bonding agent is between about 2% and about 7% of the carrier agent by weight.

151. The method of claim 149, wherein the carrier agent comprises toluene and a viscosity reducer.

152. The method of claim 151, wherein the viscosity reducer comprises ethyl alcohol.

153. The method of claim 151, wherein the ratio of toluene to the viscosity reducer is between about 70:30 to about 99:1 of the carrier agent by weight.

154. The method of claim 131, wherein the bonding agent comprises ethylcellulose.

155. The method of claim 131, wherein the bonding agent comprises polyvinyl acetate.

156. The method of claim 131, wherein the bonding agent comprises cellulose acetate.

157. The method of claim 131, wherein the bonding agent comprises a member selected from the group consisting of ethylcellulose, polyvinyl acetate, cellulose acetate, cellulose nitrate, and polyvinyl acetate chemically reacted with pyrrolidone copolymer, polyvinyl pyrrolidone and polyvinyl alcohol.

158. The method of claim 131, wherein the carrier agent comprises toluene.

159. The method of claim 132, wherein the carrier agent further comprises a viscosity reducer.

160. The method of claim 159, wherein the viscosity reducer comprises ethyl alcohol.

161. The method of claim 131, wherein the carrier agent is selected from the group consisting of an aromatic hydrocarbon, a hydro-aromatic hydrocarbon, a naval store, a chlorinated aliphatic hydrocarbon, a chlorinated aromatic hydrocarbon, a monohydric cyclic alcohol, an ether alcohol, an ether and an acetate.

162. The method of claim 131, said method further comprising the step of combining an actinic radiation blocker with the bonding layer solution prior to applying the bonding layer solution to the first surface of the support sheet.

163. The method of claim 131, said method further comprising the step of combining an antioxidant with the bonding layer solution prior to applying the bonding layer solution to the first surface of the support sheet.

164. The method of claim 131, said method further comprising the step of combining a plasticizer with the bonding layer solution prior to applying the bonding layer solution to the first surface of the support sheet.

165. The method of claim 131, wherein the bonding layer solution is applied to the support sheet in a micro-dot, discontinuous pattern.

166. The method of claim 131, wherein the bonding layer solution is applied to the support sheet in a substantially continuous pattern.

167. The method of claim 131, said method further comprising the step of applying a protective layer to the first surface of the layer of polymer resin composition such that the protective layer is removably adhered thereto.

168. The method of claim 167, wherein the protective layer is opaque.

169. The method of claim 167, wherein the protective layer comprises an actinic radiation blocker.

170. The method of claim 167, wherein the protective layer is distinguishable from the support sheet.

171. The method of claim 120, said method further comprising the step of applying a protective layer to the layer of polymer resin composition such that the protective layer is removable therefrom.

172. The method of claim 171, wherein the protective layer is opaque.

173. The method of claim 171, wherein the protective layer comprises an actinic radiation blocker.

174. The method of claim 171, wherein the protective layer is distinguishable from the support sheet.

175. A method of making a photo-sensitive laminate film for use in creating an image mask for etching an image on a substrate, said method comprising the steps of:
applying a layer of polymer resin composition having photocrosslinkability to a first surface of a support sheet; and
applying adhesive to a second surface of the support sheet.

176. The method of claim 175, said method further comprising the steps of:
creating an image mask from the layer of polymer resin composition, the image mask being defined by a predetermined pattern having a first surface and second surface, the second surface of the image mask being attached to the first surface of the support sheet; and
operatively attaching the support sheet to the substrate by allowing the adhesive located on the second surface of the support sheet to come in contact with the substrate.

177. The method of claim 176, said method further comprising the step of etching the substrate with an image corresponding inversely to the predetermined pattern of the image mask.

178. The method of claim 175, said method further comprising the step of applying an adhesive protection layer to the adhesive such that the adhesive protection layer is removably adhered thereto.

179. The method of claim 178, said method further comprising the steps of:
creating an image mask from the layer of polymer resin composition, the image mask being defined by a predetermined pattern having a first surface and second surface, the second surface of the image mask being operatively attached to the first surface of the support sheet;
removing the adhesive protection layer; and
operatively attaching the support sheet to the substrate by allowing the adhesive located on the second surface of the support sheet to come in contact with the substrate.

180. The method of claim 179, said method further comprising the step of etching the substrate with an image corresponding inversely to the predetermined pattern of the image mask.

181. A method of making a photo-sensitive laminate film for use in creating an image mask for etching an image on a substrate, said method comprising the step of applying a layer of polymer resin composition having photocrosslinkability to a first surface of a support sheet.

182. The method of claim 181, said method further comprising the step of creating an image mask from the layer of polymer resin composition, the image mask being defined by a predetermined pattern having a first surface and second surface, the second surface of the image mask being operatively attached to the first surface of a support sheet.

183. The method of claim 182, said method further comprising the step of operatively attaching a second surface of the support sheet to the substrate.

184. The method of claim 183, said method further comprising the step of etching the substrate with an image corresponding inversely to the predetermined pattern of the image mask.

185. A method comprising the steps of:
applying a fractionally-releasable bonding layer to a first surface of a support sheet; and
applying an image to at least a portion of the fractionally-releasable bonding layer such that the image is capable of separating from the support sheet.

186. The method of claim 185, wherein the step of applying an image to at least a portion of the fractionally-releasable bonding layer comprises the steps of:
placing a first stencil having a first surface and a second surface in juxtaposition with the fractionally-releasable bonding layer such that the second surface of the first stencil is in juxtaposition with the fractionally-releasable bonding layer, the first stencil having at least a first predetermined portion which allows fluid flow therethrough and at least a second predetermined portion which does not allow fluid flow therethrough;
applying a first fluid on the first surface of the first stencil such that at least a portion of the first fluid which is applied over the first predetermined portion of the first stencil passes therethrough to be deposited onto the the fractionally-releasable bonding layer to comprise the image; and
removing the first stencil therefrom.

187. The method of claim 186, wherein the first fluid is a rubberized ink.

188. The method of claim 187, said method further comprising the step of operatively attaching the image to a substrate.

189. The method of claim 188, said method further comprising the step of removing the support sheet, thereby separating the image from the support sheet.

190. The method of claim 186, wherein the first fluid comprises a colored medium.

191. The method of claim 190, wherein the colored medium is paint.

192. The method of claim 191, said method further comprising the step of operatively attaching the image to a substrate.

193. The method of claim 192, said method further comprising the step of removing the support sheet, thereby separating the image from the support sheet.

194. The method of claim 186, said method further comprising the steps of:
placing a second stencil having a first surface and a second surface in juxtaposition with the fractionally-releasable bonding layer such that the second surface of the second stencil is in juxtaposition with the fractionally-releasable bonding layer, the second stencil having at least a first predetermined portion which allows fluid flow therethrough and at least a second predetermined portion which does not allow fluid flow therethrough;
applying a second fluid on the first surface of the second stencil such that at least a portion of the second fluid which is applied over the first predetermined portion of the second stencil passes therethrough to be deposited onto the the fractionally-releasable bonding layer to comprise the image; and
removing the second stencil therefrom.

195. The method of claim 194, wherein the second fluid is a rubberized ink.

196. The method of claim 194, wherein the second fluid comprises a colored medium.

197. The method of claim 196, wherein the colored medium is paint.
